(19) United States
(12) Patent Application Publication
(10) Pub. No.: US 2023/0296981 A1
(43) Pub. Date: Sep. 21, 2023

(54) RESIST MATERIAL AND PATTERNING PROCESS

(71) Applicant: SHIN-ETSU CHEMICAL CO., LTD., Tokyo (JP)

(72) Inventors: Gentaro HIDA, Joetsu-shi (JP); Tomohiro KOBAYASHI, Joetsu-shi (JP); Yutaro OTOMO, Joetsu-shi (JP); Tomonari NOGUCHI, Joetsu-shi (JP)

(73) Assignee: SHIN-ETSU CHEMICAL CO., LTD., Tokyo (JP)

(21) Appl. No.: 18/180,946

(22) Filed: Mar. 9, 2023

(30) Foreign Application Priority Data
Mar. 17, 2022 (JP) 2022-42937

(51) Int. Cl. G03F 7/039; G03F 7/38

(52) U.S. Cl. CPC G03F 7/0392; G03F 7/38

(57) ABSTRACT

Provided are: a resist material and patterning process having sensitivity, resolution, and dissolution contrast exceeding those of conventional positive-type resist materials, having reduced edge roughness and size variation, and having a good pattern shape after exposure. A resist material, including: (Ia) a polymer having a repeating unit (A) having a hydroxy group or a carboxy group; (II) a crosslinker having a structure represented by the following formula (1); (III) a thermal acid generator having a structure represented by the following formula (2); (IV) an organic solvent; and (V) a component to be decomposed by irradiation of active ray or radiation to generate an acid.

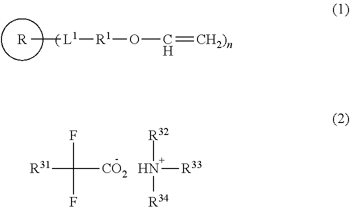

### TECHNICAL FIELD

The present invention relates to a resist material and a patterning process.

### BACKGROUND ART

As higher integration and higher speed of LSI, pattern rule has been rapidly miniaturized. This is because high-speed communication with 5G and artificial intelligence (AI) have become widespread, and a high-performance device to process them has been required. As the latest microfabrication technique, 5-nm node devices are industrially manufactured using lithography with extreme ultraviolet ray (EUV) having a wavelength of 13.5 nm. Furthermore, investigation using the EUV lithography is being progressed with a 3-nm node device, next generation, and a 2-nm node device, next to the next generation.

In lithography using a DUV light source, that is, KrF and ArF excimer lasers, chemically amplified resists in which an acid generated from a photosensitive agent with exposure catalyzes a reaction of the base polymer resin to change the solubility in a developing liquid achieves high-sensitive and high-resolution lithography. The lithography took initiative of the miniaturization as a major resist used in the practical production process.

Also, in the next-generation lithography such as EUV, the chemically amplified resist is continuously and widely investigated, leading to the commercial production. Meanwhile, with the miniaturization, demands for improvement of the resist performance has been further increased. In particular, variation of a resist pattern size (line edge roughness: LER) affects variation of a pattern size after substrate processing, and can eventually affect operation stability of the devices. Thus, the LER is required to be reduced to the minimum.

Proposed as factors of the LER in the chemically amplified resist are characteristics of a change curve of a dissolution rate relative to an exposure dose (dissolution contrast), length of acid diffusion, compatibility of the mixed composition, etc. In addition thereto, effects of the chain length, molecular size, and molecular weight of the polymer resin have recently attracted attention. Reducing the molecular weight of the polymer to reduce a dissolution unit during the development is considered to be effective for reducing the LER.

However, reducing the molecular weight of the base polymer may cause problems of pattern collapse due to decrease in strength, enhancement of the acid diffusion due to decrease in glass transition point (Tg), and deterioration in resolution due to increase in solubility of an unexposed portion in the developing liquid. To solve these problems, crosslinking the polymer chains with an acid-decomposable crosslinking group is attempted. Such crosslinking can increase the molecular weight in advance, and the acid generated during the exposure can decompose the crosslink in the exposed portion. Patent Document 1 discloses a crosslinkable polymer obtained by reacting a unit having a carboxy group or a hydroxy group and a divinyl ether unit.

Meanwhile, the crosslinkable polymer to be generated by crosslinking the polymer chains has an excessively large molecular weight. When stored as a resist solution in a long time, the polymer has a problem of aggregating each other to increase the number of defects.

Patent Document 2 discloses a resist material containing a polymer having a reactive portion and a monomer crosslinker.

Furthermore, Patent Document 3 discloses a positive-type thermosensitive resist material to achieve an intramolecular crosslinking by containing a polymer having a reactive portion, a monomer crosslinker, and a thermal acid generator.

However, such a resist material has a problem that the crosslinking reaction between the crosslinker and the polymer insufficiently proceeds in the calcining process after applying the resist material on a substrate, and the remained monomeric component adversely affects the lithographic performance. There is another problem that the acid generated in the exposed portion by an action of the photoacid generator diffuses toward the unexposed portion and easily decomposes the crosslinked structure. In addition, adding an acid into the resist solution to promote the crosslinking reaction proceeds the crosslinking reaction during the solution storage, leading to problems of storage stability such as a change in film thickness.

### CITATION LIST

### Patent Literature

Patent Document 1: JP 5562651 B
Patent Document 2: WO2018/079449 A1
Patent Document 3: JP 2000-187326 A

### SUMMARY OF INVENTION

### Technical Problem

In a resist containing a compound having a vinyl ether group as a crosslinker, an addition reaction to a carboxy group or a hydroxy group forms an acetal structure. Meanwhile, the generated acetal structure is easily decomposed by an action of a strong acid component generated from the photoacid generator, resulting in a low molecular-weight resist film in the exposed portion, and a high molecular-weight resist film in the unexposed portion. Such a resist can improve the dissolution contrast.

However, in conventional crosslinker-containing resist, a calcining step in a short time does not sufficiently proceed the crosslinking reaction, and the crosslinker remains in an unreacted state. In addition, since the acetal structure is extremely easily decomposed, diffusion of the strong acid component generated in the exposed portion easily decomposes the acetal structure to generate a monomer component. Such a component exhibits a plasticizer-like effect in the resist film to decrease glass transition point of the film, and enhances the diffusion of the acid generated with exposure to cause a problem of deterioration in the lithographic performance. In addition, adding an acid into the resist solution to promote the crosslinking reaction has a problem of storage stability due to the proceeding of an undesired crosslinking reaction during the solution storage.

The present invention has been made in view of the above circumstances. An object of the present invention is to provide: a resist material and patterning process having sensitivity, resolution, and dissolution contrast exceeding those of conventional positive-type resist materials, having reduced edge roughness and size variation, and having a good pattern shape after exposure.

### Solution to Problem

To solve the problem, the present invention provides a resist material, comprising:
(Ia) a polymer having a repeating unit (A) having a hydroxy group or a carboxy group;
(II) a crosslinker having a structure represented by the following formula (1);
(III) a thermal acid generator having a structure represented by the following formula (2);
(IV) an organic solvent; and
(V) a component to be decomposed by irradiation of active ray or radiation to generate an acid,

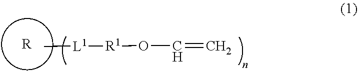

wherein R represents an n-valent organic group optionally having a substituent,

L¹ represents a linking group selected from a single bond, an ester bond, and an ether bond, and

R¹ represents a single bond or a divalent organic group, and “n” represents an integer of 1 to 4,

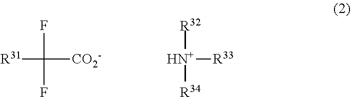

wherein R³¹ represents a monovalent organic group optionally having a heteroatom or a substituent; R³² to R³⁴ each independently represent a monovalent hydrocarbon group having 1 to 15 carbon atoms and optionally having a heteroatom, and any two of R³², R³³, and R³⁴ are optionally bonded each other to from a ring together with the nitrogen atom to which R³², R³³, and R³⁴ are bonded.

Such a resist material can provide a resist material having reduced edge roughness and size variation after the exposure, excellent resolution, good pattern shape after the exposure, and good storage stability.

The present invention also provides a resist material, comprising:
(Ib) a polymer having: a repeating unit (A) having a hydroxy group or a carboxy group; and a repeating unit (C) having a structural moiety to be decomposed by irradiation of active ray or radiation to generate an acid;
(II) a crosslinker having a structure represented by the following formula (1);
(III) a thermal acid generator having a structure represented by the following formula (2); and
(IV) an organic solvent,

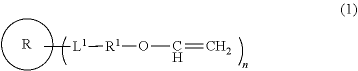

wherein R represents an n-valent organic group optionally having a substituent;

L¹ represents a linking group selected from a single bond, an ester bond, and an ether bond; and

R¹ represents a single bond or a divalent organic group, and “n” represents an integer of 1 to 4,

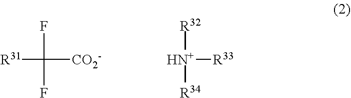

wherein R³¹ represents a monovalent organic group optionally having a heteroatom or a substituent; and R³² to R³⁴ each independently represent a monovalent hydrocarbon group having 1 to 15 carbon atoms and optionally having a heteroatom, and any two of R³², R³³, and R³⁴ are optionally bonded each other to from a ring together with the nitrogen atom to which R³², R³³, and R³⁴ are bonded.

Such a resist material can provide a resist material having reduced edge roughness and size variation after the exposure, excellent resolution, good pattern shape after the exposure, and good storage stability.

The repeating unit (C) in the polymer is preferably represented by the following formula (c),

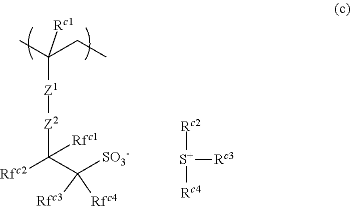

wherein R^{c1} represents a hydrogen atom or a methyl group;

Z¹ represents a single bond or an ester bond; Z² represents a single bond or a divalent organic group having 1 to 25 carbon atoms and optionally having one or more of an ester bond, an ether bond, a lactone ring, an amide bond, a sultone ring, and an iodine atom;

Rf^{c1} to Rf^{c4} each independently represent a hydrogen atom, a fluorine atom, or a trifluoromethyl group, and at least one of Rf^{c1} to Rf^{c4} represents a fluorine atom or a trifluoromethyl group; and

R^{c2} to R^{c4} each independently represent a monovalent hydrocarbon group having 1 to 20 carbon atoms and optionally having a heteroatom, and any two of R^{c2}, R^{c3}, and R^{c4} are optionally bonded each other to form a ring together with the sulfur atom to which R^{c2}, R^{c3}, and R^{c4} are bonded.

Such a resist material can provide a resist material having good solubility in an alkaline developing liquid.

The above resist material preferably further comprises (V) a component to be decomposed by irradiation of active ray or radiation to generate an acid.

Such a resist material can improve the dissolution contrast to the unexposed portion.

The repeating unit (A) in the polymer is preferably represented by the following formulae (a1) and/or (a2),

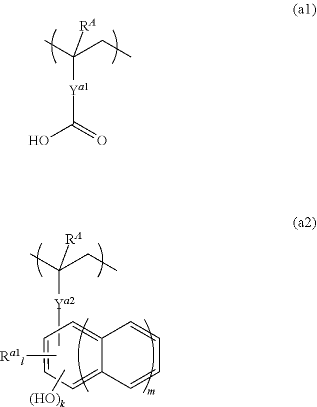

wherein R^{A} each independently represents a hydrogen atom or a methyl group; Y^{a1} each independently represents a single bond or a divalent linking group having 1 to 15 carbon atoms and having at least one or more of a phenylene group, a naphthylene group, an ester bond, an ether bond, a lactone ring, an amide group, and a heteroatom; Y^{a2} each independently represents a single bond or a divalent linking group having 1 to 12 carbon atoms and having at least one or more of a phenylene group, a naphthylene group, an ester bond, an ether bond, a lactone ring, an amide group, and a heteroatom; R^{a1} represents a hydrogen atom, a fluorine atom, or an alkyl group, and R^{a1} and Y^{a2} are optionally bonded to form a ring; “k” represents 1 or 2; “l” represents an integer of 0 to 4; 1≤k+l≤5; and “m” represents 0 or 1.

Such a resist material can inhibit the diffusion of an acid generated in the exposed portion by an action of the photoacid generator.

R³¹ in the formula (2) preferably has an iodine atom.

Such a resist material can promote the crosslinking reaction of the polymer in the resist material on the substrate.

R in the formula (1) preferably has an aromatic hydrocarbon group.

Such a resist material can improve the contrast between the exposed portion and the unexposed portion.

The above resist material preferably further comprises (VI) a quencher.

Such a resist material can inhibit the diffusion of an acid generated by an action of the photoacid generator in the exposed portion.

The present invention also provides a patterning process, comprising:
(i) a step of forming a resist film by applying a resist material on a substrate using the above resist material;
(ii) a step of exposing the resist film with a high-energy ray; and
(iii) a step of developing the exposed resist film using a developing liquid.

Such a patterning process can yield a pattern having reduced edge roughness and size variation, excellent resolution, and good pattern shape after the exposure.

The step (i) preferably further comprises a step of prebaking the resist film at 130° C. or higher.

Such a patterning process can efficiently proceed the crosslinking reaction with the crosslinker.

### Advantageous Effects of Invention

The inventive resist material contains the polymer having the reactive group and the vinyl ether crosslinker, and in addition, the ammonium carboxylate salt-type thermal acid generator. This thermal acid generator generates a weak acid by heating in a calcining step to promote the crosslinking reaction. The fluorocarboxylic acid to be generated has appropriate acidity for promoting the crosslinking reaction. Meanwhile, since being a weak-acid salt, the thermal acid generator added in the resist solution does not cause undesired crosslinking reaction during the solution storage, and thus the problem on storage stability is solved.

When the resist material contains the quencher component, the effect of the quencher component can provide a neutral environment in the solution state and provide a weakly acidic environment in a micro-exposed region, and thereby the quencher component can trap the acid generated in the exposed portion to further inhibit the acid diffusion.

The inventive resist material, which contains the specific thermal acid generator and vinyl ether crosslinker, efficiently proceeds the crosslinking reaction of the polymer chain with the above effect. Thus, the inventive resist material yields excellent pattern shape, roughness, and resolution after the exposure, and has good storage stability, and thereby extremely high practicality. Specifically, the inventive resist material is extremely useful for fine-pattern formation materials for, particularly, VLSI or a photomask with EB writing, or pattern formation materials for EB or EUV lithography. The inventive resist material can be applied for, for example, not only the lithography of semiconductor circuit formation but also formation of a mask circuit pattern, micromachines, and of a thin-film magnetic head circuit.

### BRIEF DESCRIPTION OF DRAWING

FIG. 1 is a graph comparing contrasts in the inventive Examples and Comparative Examples.

### DESCRIPTION OF EMBODIMENTS

As noted above, there have been demands for the developments of a resist material having reduced edge roughness and size variation, excellent resolution, good pattern shape after the exposure, and good storage stability.

The present inventors have earnestly studied to solve the above problem, and consequently completed the present invention that can form a pattern having reduced LER and excellent resolution with a resist containing: a polymer compound having a specific functional group; a specific vinyl ether crosslinker; and a specific carboxylate salt-type thermal acid generator. The present invention can also overcome the storage stability problem.

Specifically, the first aspect of the present invention is a resist material, comprising:
(Ia) a polymer having a repeating unit (A) having a hydroxy group or a carboxy group;
(II) a crosslinker having a structure represented by the following formula (1);
(III) a thermal acid generator having a structure represented by the following formula (2);
(IV) an organic solvent; and
(V) a component to be decomposed by irradiation of active ray or radiation to generate an acid,

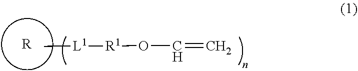

wherein R represents an n-valent organic group optionally having a substituent,

L¹ represents a linking group selected from a single bond, an ester bond, and an ether bond,

R¹ represents a single bond or a divalent organic group, and “n” represents an integer of 1 to 4,

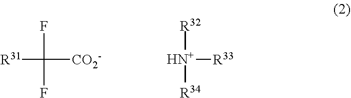

wherein R³¹ represents a monovalent organic group optionally having a heteroatom or a substituent; R³² to R³⁴ each independently represent a monovalent hydrocarbon group having 1 to 15 carbon atoms and optionally having a heteroatom, and any two of R³², R³³, and R³⁴ are optionally bonded each other to from a ring together with the nitrogen atom to which R³², R³³, and R³⁴ are bonded.

The second aspect of the present invention is a resist material, comprising:
(Ib) a polymer having: a repeating unit (A) having a hydroxy group or a carboxy group; and a repeating unit (C) having a structural moiety to be decomposed by irradiation of active ray or radiation to generate an acid;
(II) a crosslinker having a structure represented by the following formula (1);
(III) a thermal acid generator having a structure represented by the following formula (2); and
(IV) an organic solvent,

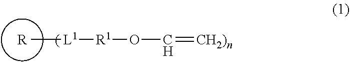

wherein R represents an n-valent organic group optionally having a substituent;

L¹ represents a linking group selected from a single bond, an ester bond, and an ether bond; and

R¹ represents a single bond or a divalent organic group, and “n” represents an integer of 1 to 4,

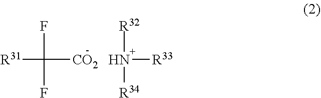

wherein R³¹ represents a monovalent organic group optionally having a heteroatom or a substituent; and R³² to R³⁴ each independently represent a monovalent hydrocarbon group having 1 to 15 carbon atoms and optionally having a heteroatom, and any two of R³², R³³, and R³⁴ are optionally bonded each other to from a ring together with the nitrogen atom to which R³², R³³, and R³⁴ are bonded.

Hereinafter, the present invention will be described in detail, but the present invention is not limited thereto.

### [First Aspect]

The first aspect of the present invention is the resist material containing the above components (Ia), (II), (III), (IV), and (V). Hereinafter, each component will be described in detail.

### (Ia) Base Polymer

The base polymer (P) in the present invention has a repeating unit (A) having a hydroxy group or a carboxy group. The repeating unit (A) functions as a reaction portion with the crosslinker (II), described later, and forms a polymer product on a substrate. This polymer product can inhibit the diffusion of the acid generated in the exposed portion by an action of the photoacid generator.

The repeating unit (A) is preferably represented by the following formula (a1) or (a2).

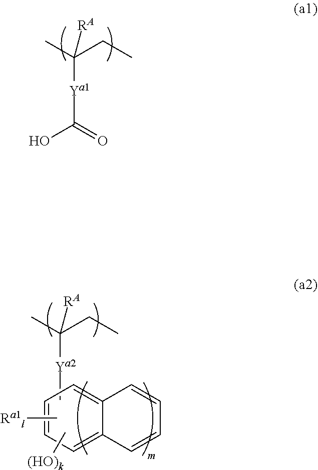

In the formulae (a1) and (a2), R^{A} each independently represents a hydrogen atom or a methyl group.

In the formula (a1), Y^{a1} each independently represents a single bond, or a divalent linking group having 1 to 15 carbon atoms and at least one or more of a phenylene group, a naphthylene group, an ester bond, an ether bond, a lactone ring, an amide group, and a heteroatom.

In the formula (a2), Y^{a2} each independently represents a single bond, or a divalent linking group having 1 to 12 carbon atoms and at least one or more of a phenylene group, a naphthylene group, an ester bond, an ether bond, a lactone ring, an amide group, and a heteroatom.

In the formula (a2), R^{a1} represents a hydrogen atom, a fluorine atom, or an alkyl group. R^{a1} and Y^{a2} are optionally bonded to form a ring.

In the formula (a2), “k” represents 1 or 2. “l” represents an integer of 0 to 4, and 1≤k+l≤5. “m” represents an integer of 0 or 1.

Examples of monomers to yield the repeating unit (a1) include the following monomers, but the monomer is not limited thereto.

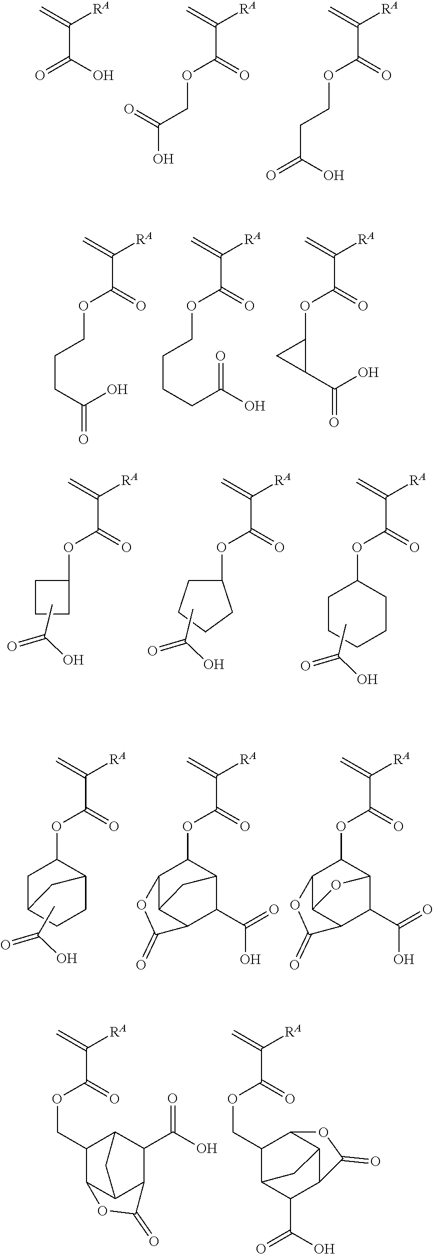

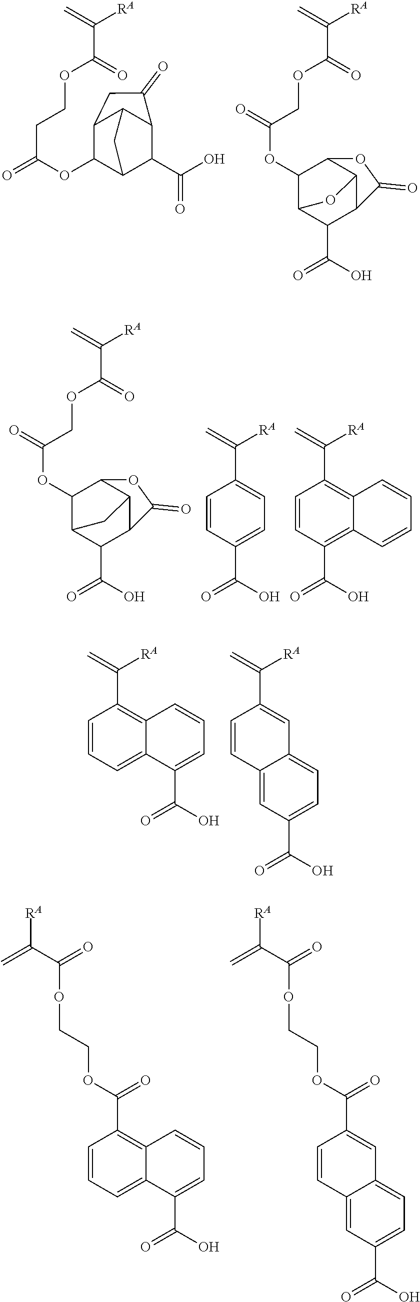

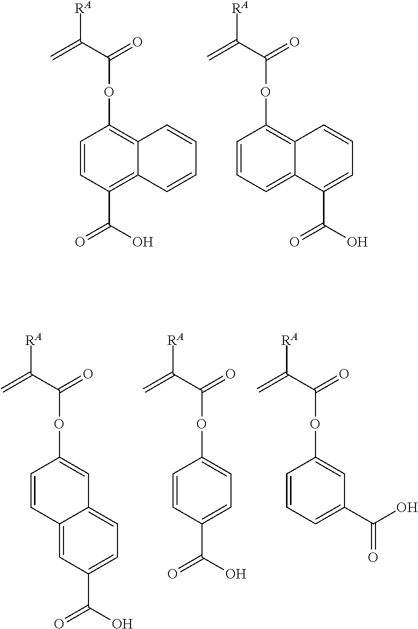

Examples of monomers to yield the repeating unit (a2) include the following monomers, but the monomer is not limited thereto.

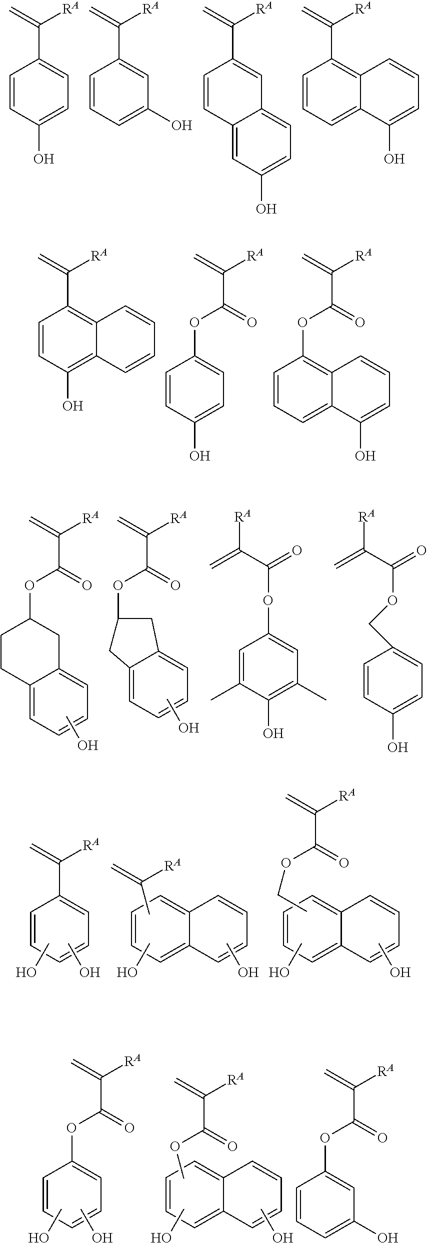

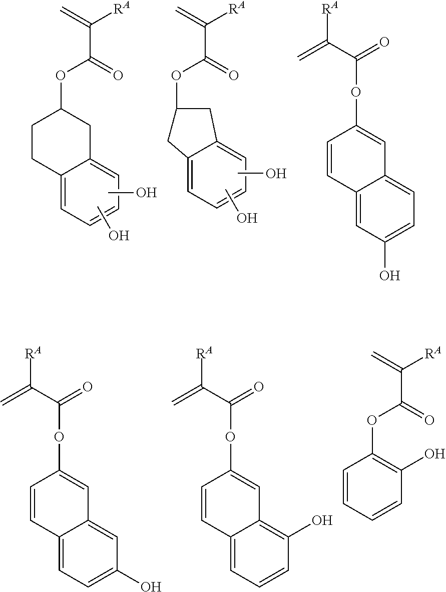

The content of the repeating unit (A) contained in the base polymer (P) is preferably 5 mol % or more, and more preferably 10 mol % or more and 80 mol % or less.

As the repeating unit (A), a repeating unit other than the repeating unit (a1) or (a2) can also be used.

The base polymer (P) preferably further has a repeating unit (B) in which the hydrogen atom of the carboxy group in the repeating unit (A) is substituted with an acid-labile group. Methods for changing the solubility of the resist film in a developing liquid mainly include changing the molecular weight and changing the polarity. Since an effect of changing the molecular weight can be obtained by an action of the crosslinker (II), and an effect of changing the polarity can be obtained by the repeating unit (B). Thus, the contrast can be remarkably improved.

The repeating unit (B) is preferably represented by the following formula (b).

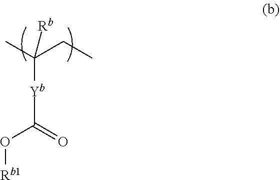

In the formula (b), R^{b} represents a hydrogen atom or a methyl group. Y^{b} represents a single bond, or a divalent linking group having 1 to 15 carbon atoms and at least one or more of a phenylene group, a naphthylene group, an ester bond, an ether bond, a lactone ring, an amide group, and a heteroatom. R^{b1} represents the acid-labile group.

Examples of monomers to yield the repeating unit (b) include the following monomers, but the monomer is not limited thereto.

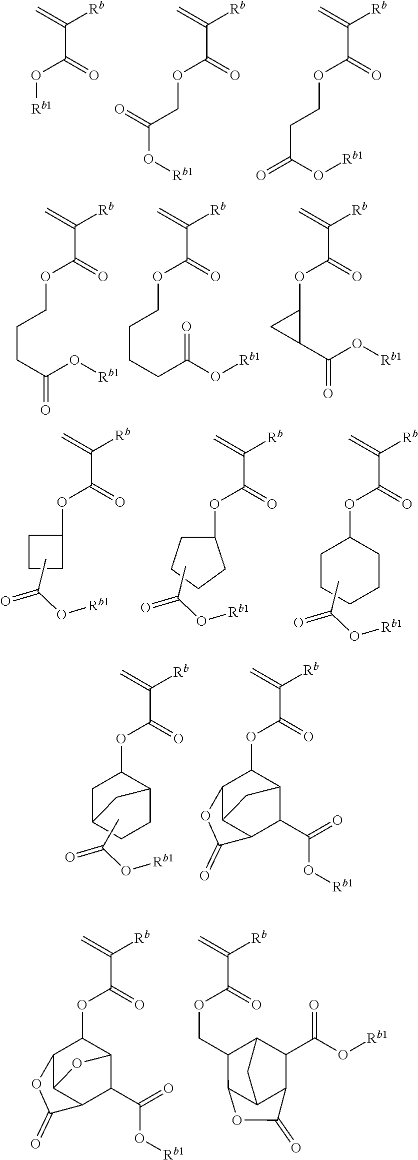

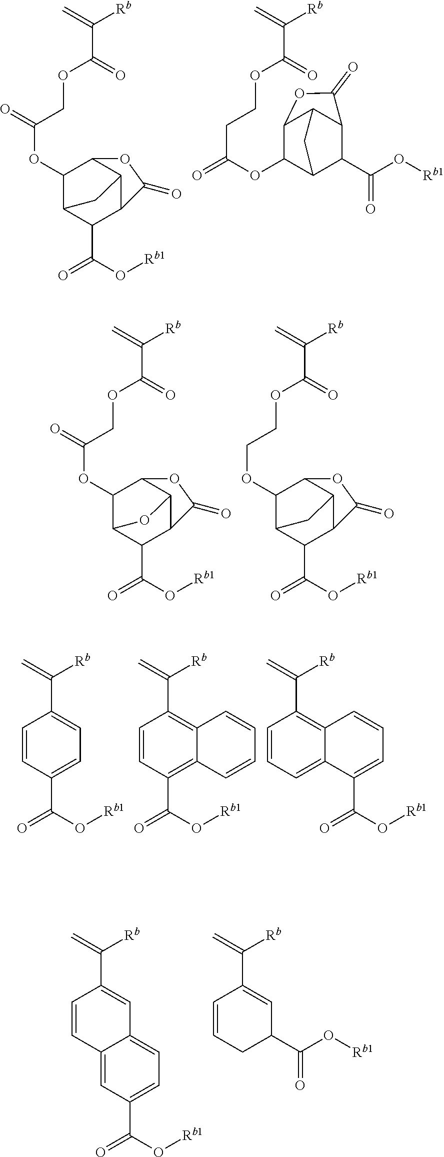

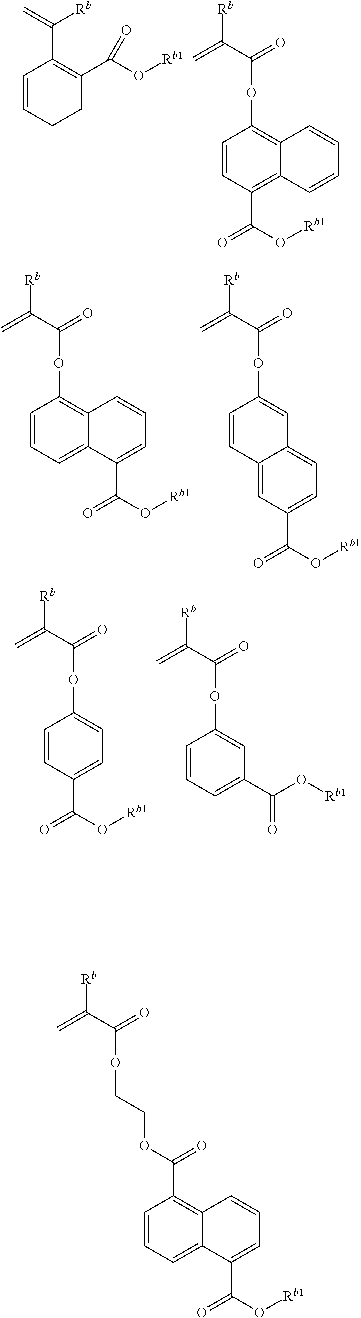

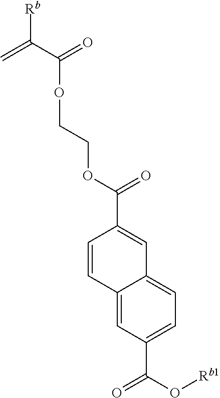

Examples of the acid-labile group represented by R^{b1} include groups represented by the following formulae (AL-3)-1 to (AL-3)-19, but the acid-labile group is not limited thereto.

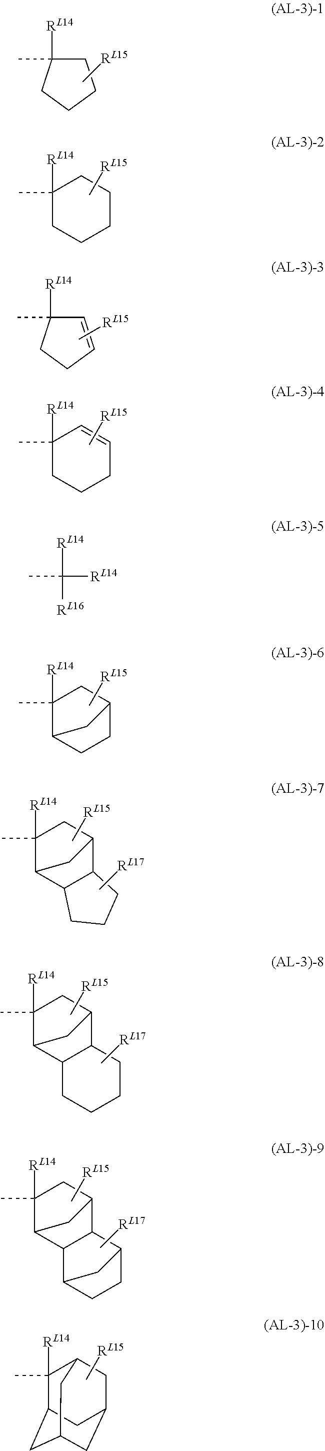

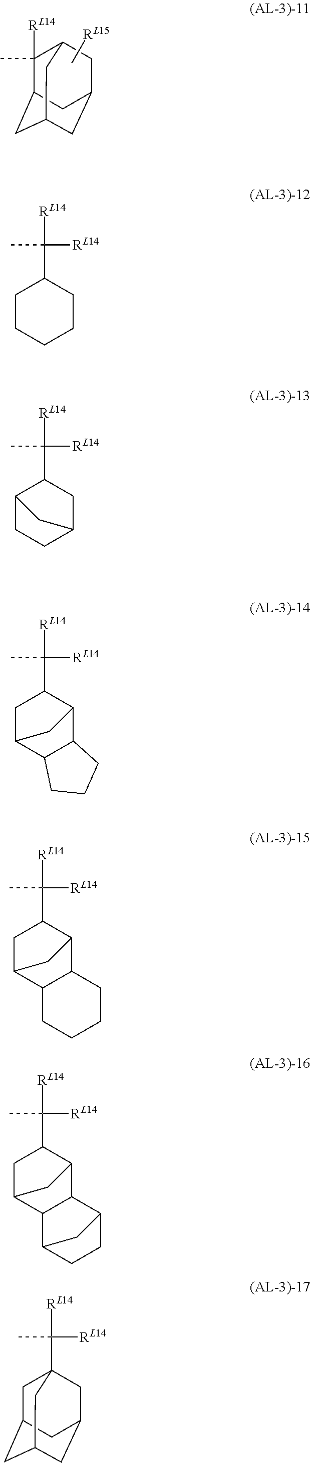

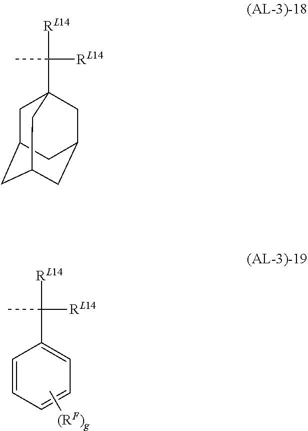

In the formulae, a broken line represents a bond.

In the formulae (AL-3)-1 to (AL-3)-19, R^{L14} each independently represents a saturated hydrocarbyl group having 1 to 8 carbon atoms or an aryl group having 6 to 20 carbon atoms. R^{L15} and R^{L17} each independently represent a hydrogen atom or a saturated hydrocarbyl group having 1 to 20 carbon atoms. R¹⁶ represents an aryl group having 6 to 20 carbon atoms. The saturated hydrocarbyl group may be any of linear, branched, and cyclic groups. The aryl group is preferably a phenyl group, etc. RF represents a fluorine atom or a trifluoromethyl group. “g” represents an integer of 1 to 5.

The content of the repeating unit (B) contained in the base polymer (P) is preferably 90 mol % or less, and more preferably 70 mol % or less and 20 mol % or more.

### (II) Crosslinker

The crosslinker (II) in the present invention has a vinyl ether group to cause an addition reaction with the carboxy group or the hydroxy group in the structural unit (A) of the base polymer (P). Crosslinking between the base polymers on a substrate significantly increases the molecular weight to inhibit the acid diffusion and the dissolution in a developing liquid. An acetal structure formed after the crosslinking reaction is decomposed by a strong acid component generated from the component (V), which is to generate an acid by the exposure, described later, to lower the molecular weight only in the exposed portion. Therefore, the contrast between the exposed portion and the unexposed portion is improved.

The crosslinker (II) has a structure represented by the following formula (1).

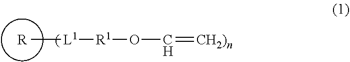

In the formula (1), L¹ represents a linking group selected from a single bond, an ester bond, and an ether bond.

In the formula (1), R¹ represents a single bond or a divalent organic group.

In the formula (1), R represents an n-valent organic group optionally having a substituent. R preferably has a cyclic structure, and the cyclic structure is more preferably an aromatic hydrocarbon group.

In the formula (1), “n” represents an integer of 1 to 4. “n” preferably represents 2 or more.

Examples of the crosslinker (II) include the following compounds, but the crosslinker is not limited thereto.

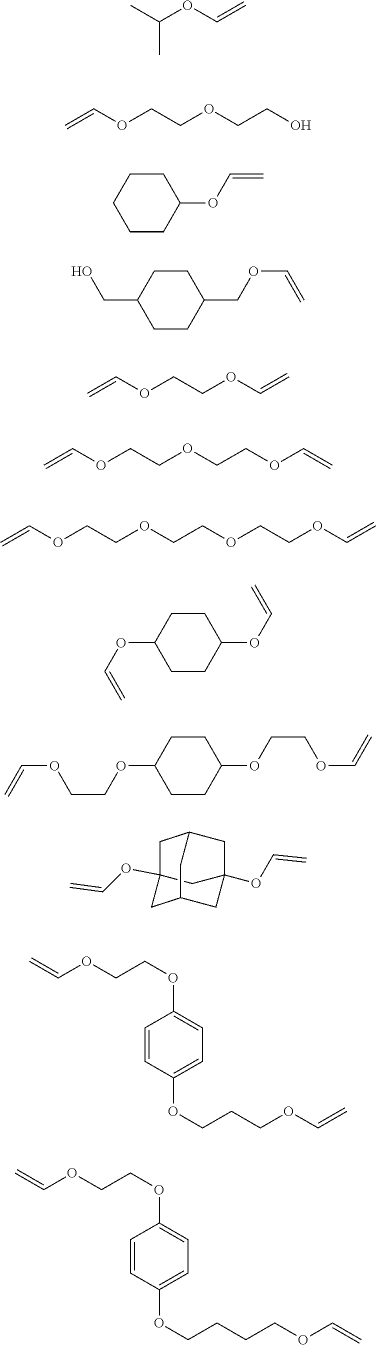

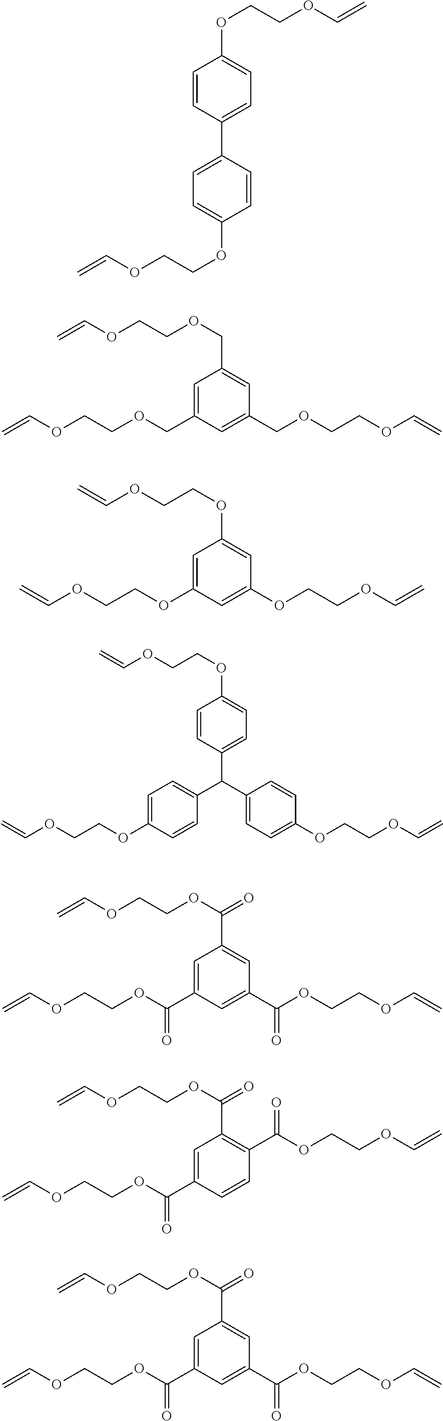

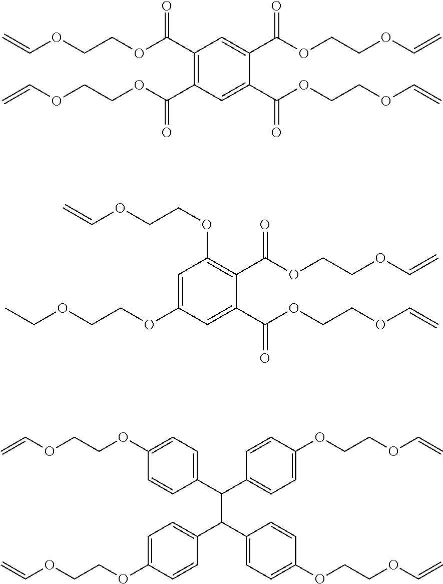

The content of the crosslinker (II) is preferably 0.1 to 50 parts by mass, and more preferably 1 to 40 parts by mass, relative to 100 parts by mass of the base polymer. The crosslinker (II) may be used singly, or may be used in combination of two or more kind thereof.

### (III) Thermal Acid Generator

The thermal acid generator (III) in the present invention is a component to promote the crosslinking reaction with an acid generated in the calcining step.

The thermal acid generator (III) is a weak-acid salt composed of a carboxylate anion and an ammonium cation. The acid generated in the system promotes the crosslinking reaction, but does not contribute to the decomposition of the formed acetal bond.

The thermal acid generator (III) has a structure represented by the following formula (2).

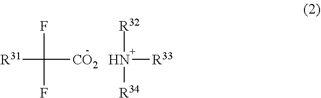

In the formula (2), R³¹ represents a monovalent organic group optionally having a heteroatom or a substituent. The organic group optionally has an ether bond, an ester bond, an amide bond, a lactone ring, or a sultone ring. R³¹ preferably represents a group having an aromatic hydrocarbon group, and more preferably represents a group having an iodine atom.

In the formula (2), R³² to R³⁴ each independently represent a monovalent hydrocarbon group having 1 to 15 carbon atoms and optionally having a heteroatom. Any two of R³², R³³, and R³⁴ are optionally bonded each other to from a ring together with the nitrogen atom to which R³², R³³, and R³⁴ are bonded.

Examples of the anion structure of the thermal acid generator (III) include the following structures, but the anion structure is not limited thereto.

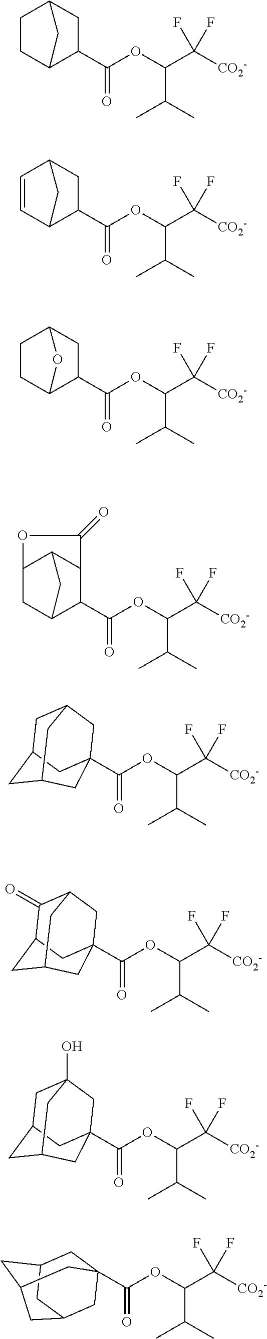

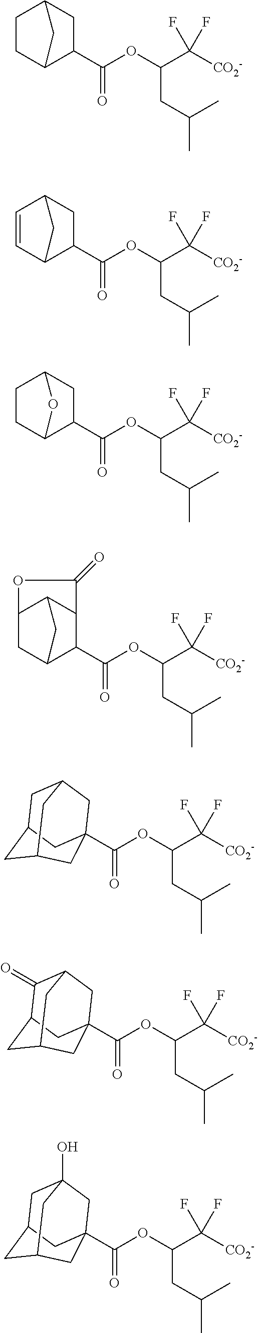

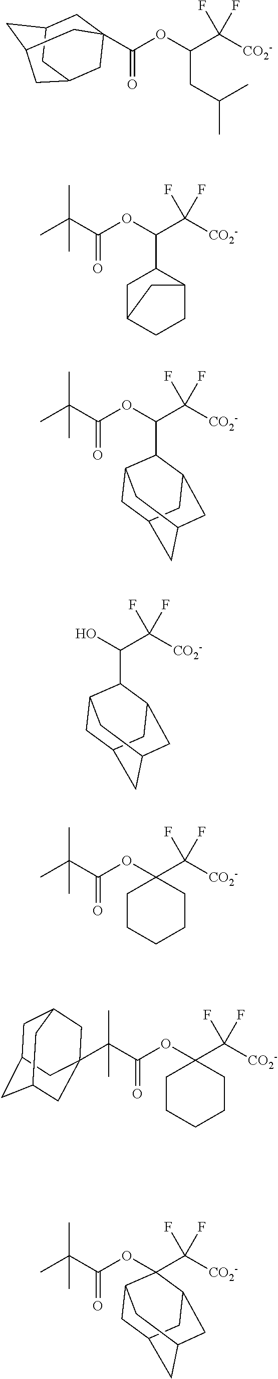

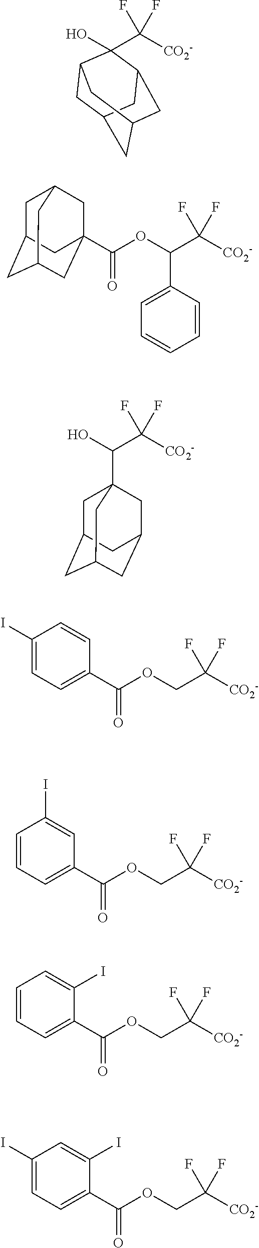

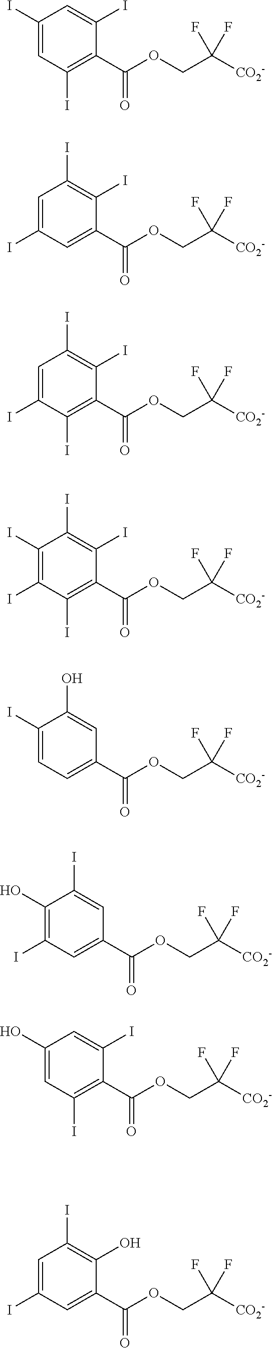

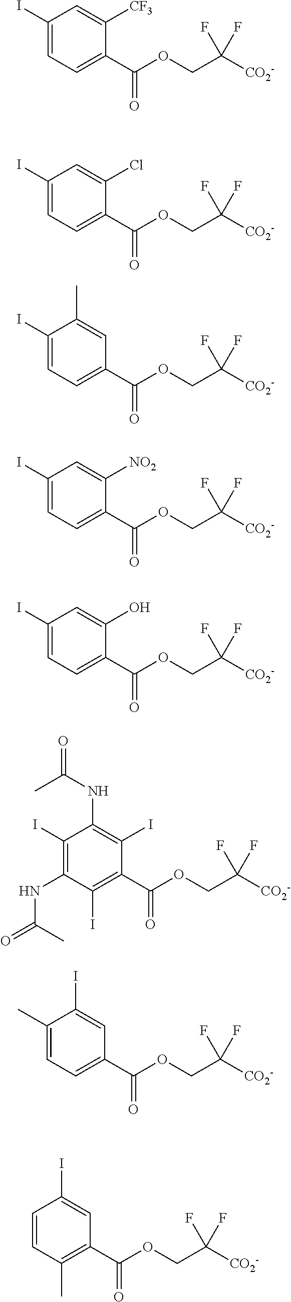

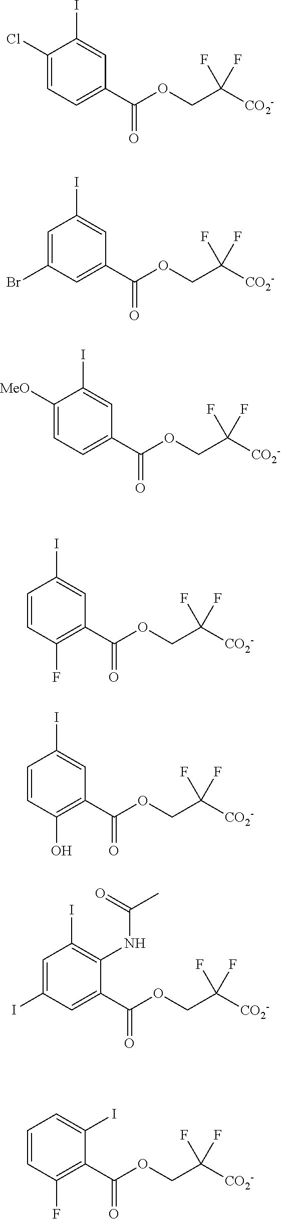

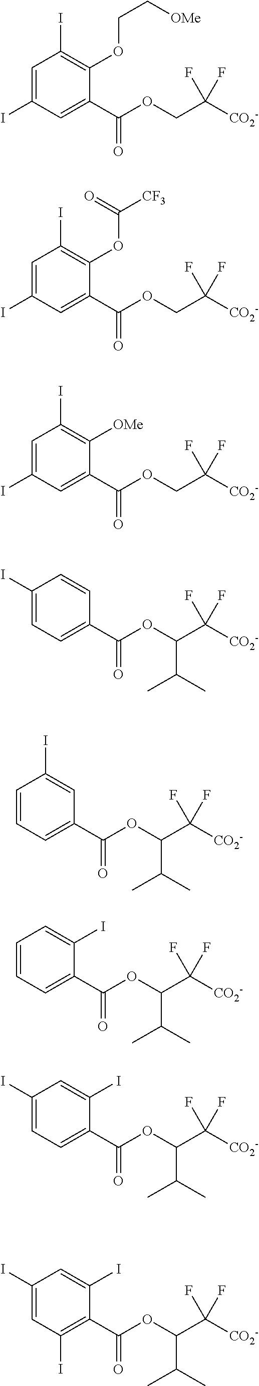

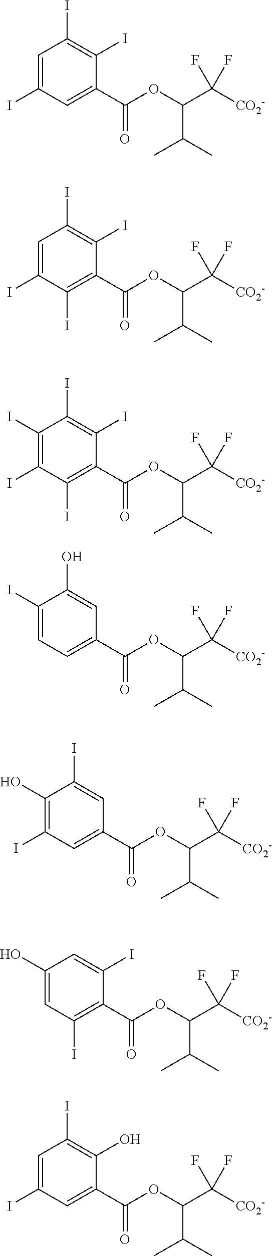

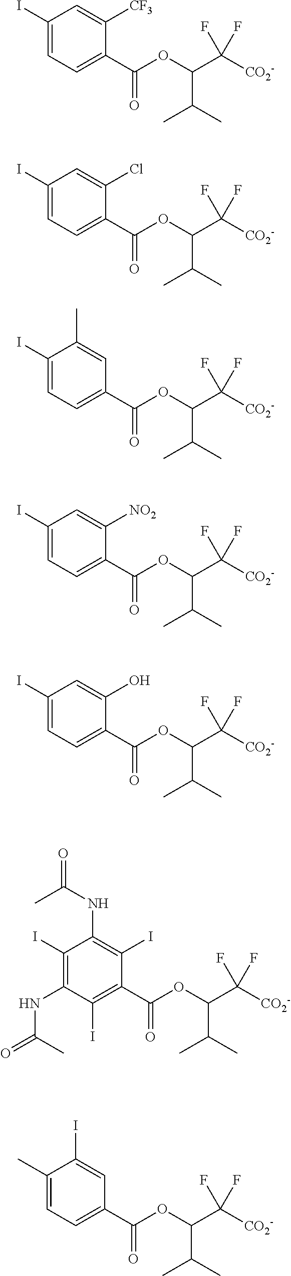

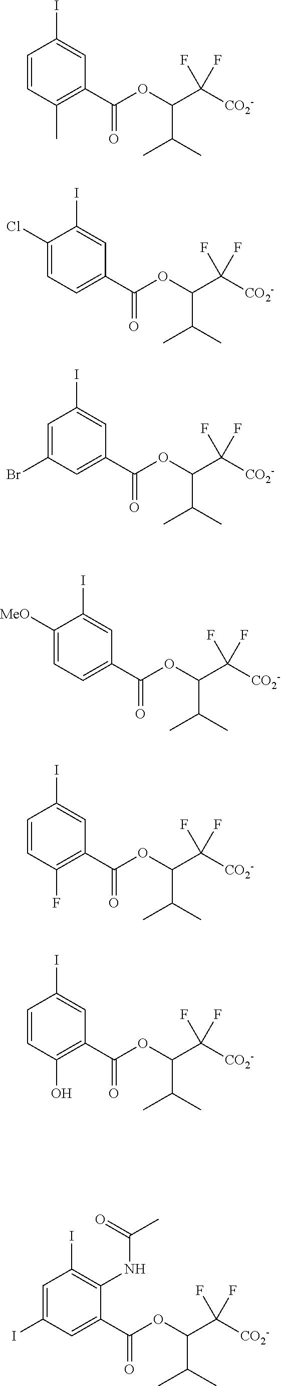

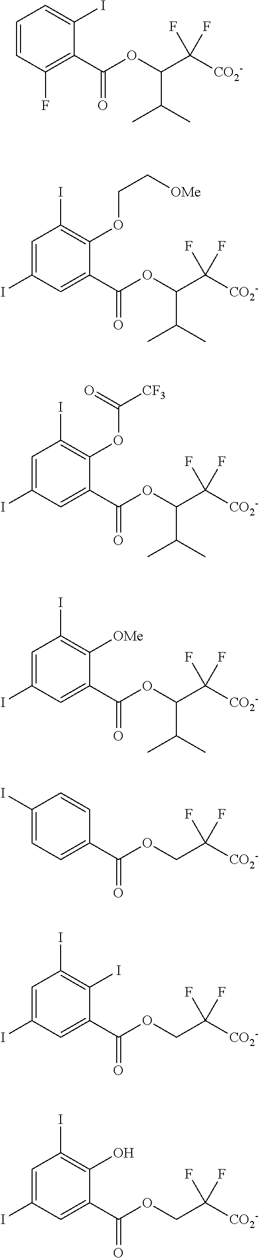

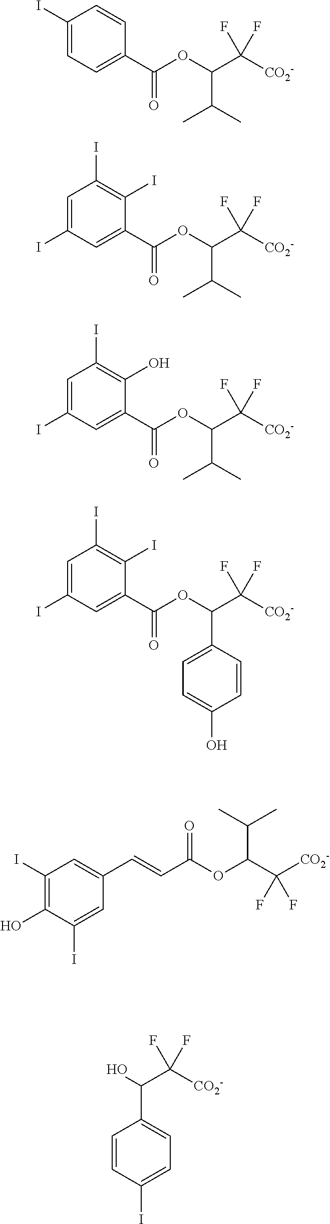

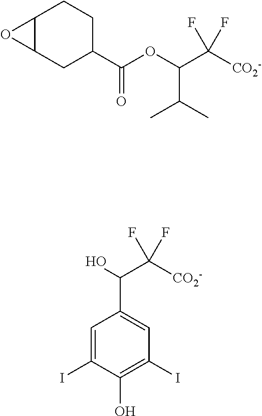

Examples of the cation structure of the thermal acid generator (III) include the following structures, but the cation structure is not limited thereto.

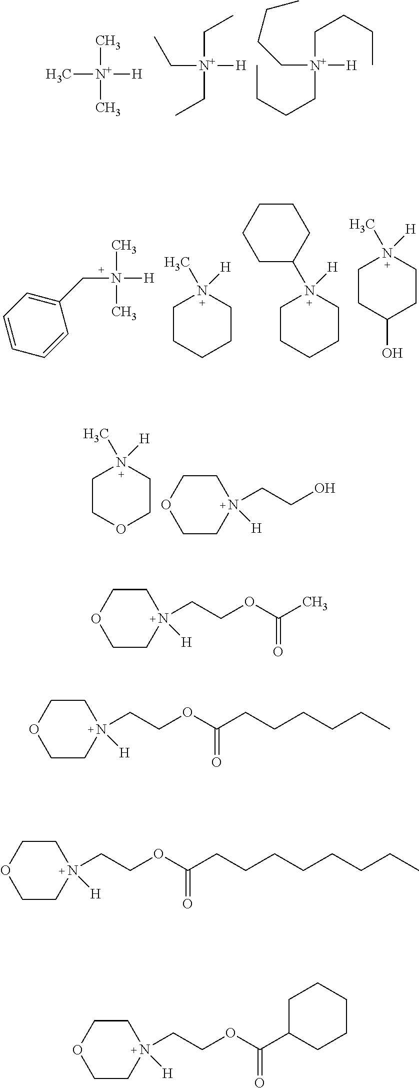

The content of the thermal acid generator (III) in the inventive resist material is preferably 0.1 to 50 parts by mass, and more preferably 1 to 40 parts by mass, relative to 100 parts by mass of the base polymer (P).

The thermal acid generator (III) can be used singly, or can be used in combination of two or more kinds thereof.

### (IV) Organic Solvent

The inventive resist material contains the organic solvent. The organic solvent is not limited as long as the solvent can dissolve each component contained in the inventive resist material. Examples of the organic solvent include, described in paragraphs [0144] to [0145] of JP 2008-111103 A: ketones, such as cyclohexanone, cyclopentanone, methyl 2-n-pentyl ketone, and 2-heptanone; alcohols, such as 3-methoxybutanol, 3-methyl-3-methoxybutanol, 1-methoxy-2-propanol, 1-ethoxy-2-propanol, and diacetone alcohol; ethers, such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters, such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones, such as γ-butyrolactone.

The content of the organic solvent in the inventive resist material is preferably 100 to 10,000 parts by mass, and more preferably 200 to 8,000 parts by mass, relative to 100 parts by mass of the base polymer. The organic solvent may be used singly, or may be used with mixing two or more kinds thereof.

### (V) Component to be Decomposed by Irradiation of Active Ray or Radiation to Generate Acid

The inventive resist material further contains a photoacid generator. An acid generated from the photoacid generator by the pattern-exposure is a strong acid having higher acidity than the quencher (VI), described later, and decomposes the acid-labile group in the repeating unit (B) and the acetal bond formed by the crosslinker (II). These decompositions change the polarity and lower the molecular weight in the exposed portion of the resist film. Therefore, the dissolution contrast to the unexposed portion is improved.

Examples of the photoacid generator include a compound to generate an acid by sensitizing with active ray or radiation. The photoacid generator may be any compound that generates an acid by high-energy ray irradiation, but a photoacid generator to generate a sulfonic acid, an imide acid, or a methide acid is preferable. Preferable photoacid generators include sulfonium salts, iodonium salts, sulfonyldiazomethanes, N-sulfonyloxyimides, and oxime-O-sulfonate-type acid generators. Specific examples of the photoacid generator include photoacid generators described in paragraphs [0122] to [0142] of JP 2008-111103 A.

The content of the photoacid generator (V) in the inventive resist material is preferably 0.1 to 50 parts by mass, and more preferably 1 to 40 parts by mass, relative to 100 parts by mass of the base polymer (P). The photoacid generator (V) can be used singly, or can be used in combination of two or more kinds thereof.

As the photoacid generator, a sulfonium salt represented by the following formula (3) can be suitably used.

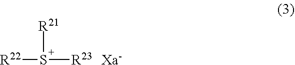

In the formula (3), R²¹ to R²³ each independently represent a halogen atom or a hydrocarbyl group having 1 to 20 carbon atoms and optionally having a heteroatom. The hydrocarbyl group may be any of linear, branched, and cyclic groups, and specific examples thereof include same groups as those exemplified in description of R^{c2} to R^{c4} in the formula (c), described later. A part or all of hydrogen atoms in these groups are optionally substituted with a group having a heteroatom, such as an oxygen atom, a sulfur atom, a nitrogen atom, and a halogen atom. A part of —CH₂— in these groups is optionally substituted with a group having a heteroatom, such as an oxygen atom, a sulfur atom, and a nitrogen atom. As a result, optionally contained are a hydroxy group, a fluorine atom, a chlorine atom, a bromine atom, an iodine atom, a cyano group, a nitro group, a carbonyl group, an ether bond, an ester bond, a sulfonate ester bond, a carbonate bond, a lactone ring, a sultone ring, a carboxylic anhydride, a haloalkyl group, etc. R²¹ and R²² are optionally bonded each other to form a ring together with the sulfur atom to which R²¹ and R²² are bonded. In this case, examples of the ring include those exemplified as rings that can be formed by bonding any two of R^{c2}, R^{c3}, and R^{c4} each other together with the sulfur atom to which R^{c2}, R^{c3}, and R^{c4} are bonded, described in the formula (c).

Examples of the cation of the sulfonium salt represented by the formula (3) include cations same as those exemplified as a sulfonium cation of a monomer to yield a repeating unit (C), described later.

In the formula (3), Xa⁻ represents an anion selected from the following formulae (3A) to (3D).

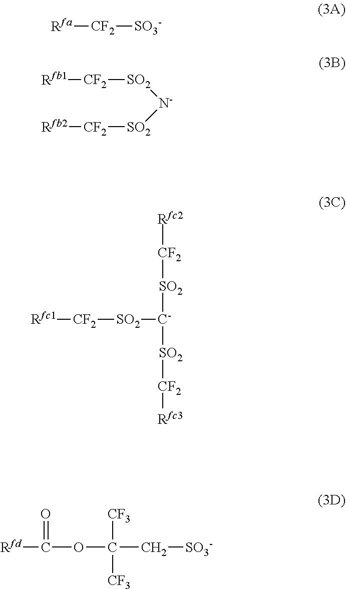

In the formula (3A), R^{fa} represents a fluorine atom, or a hydrocarbyl group having 1 to 40 carbon atoms and optionally having a heteroatom. The hydrocarbyl group may be a saturated or unsaturated group, and may be any of linear, branched, and cyclic groups. Specific examples thereof include groups same as those exemplified as a hydrocarbyl group represented by R¹¹¹ in the formula (3A′), described later.

The anion represented by the formula (3A) is preferably represented by the following formula (3A′).

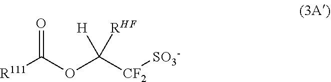

In the formula (3A′), R^{HF} represents a hydrogen atom or a trifluoromethyl group, and preferably a trifluoromethyl group. R¹¹¹ represents a hydrocarbyl group having 1 to 38 carbon atoms and optionally having a heteroatom. As the heteroatom, an oxygen atom, a nitrogen atom, a sulfur atom, a halogen atom, etc. are preferable, and an oxygen atom is more preferable. The hydrocarbyl group particularly preferably has 6 to 30 carbon atoms in terms of achievement of high resolution in fine pattern formation.

The hydrocarbyl group represented by R¹¹¹ may be a saturated or unsaturated group, and may be any of linear, branched, and cyclic groups. Specific examples thereof include: alkyl groups having 1 to 38 carbon atoms, such as a methyl group, an ethyl group, an n-propyl group, an isopropyl group, a butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an icosanyl group; cyclic saturated hydrocarbyl groups having 3 to 38 carbon atoms, such as a cyclopentyl group, a cyclohexyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group; unsaturated aliphatic hydrocarbyl groups having 2 to 38 carbon atoms, such as an allyl group and a 3-cyclohexenyl group; aryl groups having 6 to 38 carbon atoms, such as a phenyl group, a 1-naphthyl group, and a 2-naphthyl group; aralkyl groups having 7 to 38 carbon atoms, such as a benzyl group and a diphenylmethyl group; and groups obtained by combining these groups.

A part or all of hydrogen atoms in these groups are optionally substituted with a group having a heteroatom, such as an oxygen atom, a sulfur atom, a nitrogen atom, and a halogen atom. A part of —CH₂— in these groups is optionally substituted with a group having a heteroatom, such as an oxygen atom, a sulfur atom, and a nitrogen atom. As a result, optionally contained are a hydroxy group, a fluorine atom, a chlorine atom, a bromine atom, an iodine atom, a cyano group, a nitro group, a carbonyl group, an ether bond, an ester bond, a sulfonic acid ester bond, a carbonate bond, a lactone ring, a sultone ring, a carboxylic anhydride, a haloalkyl group, etc. Examples of the hydrocarbyl group having a heteroatom include a tetrahydrofuryl group, a methoxymethyl group, an ethoxymethyl group, a methylthiomethyl group, an acetamidomethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group.

Synthesis of the sulfonium salt having the anion represented by the formula (3A′) is described in detail in JP 2007-145797 A, JP 2008-106045 A, JP 2009-7327 A, and JP 2009-258695 A. Sulfonium salts described in JP 2010-215608 A, JP 2012-41320 A, JP 2012-106986 A, and JP 2012-153644 A are also preferably used.

Examples of the anion represented by the formula (3A) include anions same as those exemplified as the anion represented by the formula (1A) in JP 2018-197853 A.

In the formula (3B), R^{fb1} and R^{fb2} each independently represent a fluorine atom, or a hydrocarbyl group having 1 to 40 carbon atoms and optionally having a heteroatom. The hydrocarbyl group may be a saturated or unsaturated group, and may be any of linear, branched, and cyclic groups. Specific examples thereof include groups same as the groups exemplified as the hydrocarbyl group represented by R¹¹¹ in the formula (3A′). R^{fb1} and R^{fb2} preferably represent a fluorine atom or a linear fluorinated alkyl group having 1 to 4 carbon atoms. R^{fb1} and R^{fb2} are optionally bonded each other to form a ring together with the group to which R^{fb1} and R^{fb2} are bonded (—CF₂—SO₂—N—SO₂—CF₂—), and the group obtained in this case by bonding R^{fb1} and R^{fb2} each other is preferably a fluorinated ethylene group or a fluorinated propylene group.

In the formula (3C), R^{fc1}, R^{fc2}, and R^{fc3} each independently represent a fluorine atom or a hydrocarbyl group having 1 to 40 carbon atoms and optionally having a heteroatom. The hydrocarbyl group may be a saturated or unsaturated group, and may be any of linear, branched, and cyclic groups. Specific examples thereof include groups same as those exemplified as the hydrocarbyl group represented by R¹¹¹ in the formula (3A′). R^{fc1}, R^{fc2}, and R^{fc3} are preferably a fluorine atom or a linear fluorinated alkyl group having 1 to 4 carbon atoms. R^{fc1} and R^{fc2} are optionally bonded each other to form a ring together with the group to which R^{fc1} and R^{fc2} are bonded (—CF₂—SO₂—C—SO₂—CF₂—), and the group obtained in this case by bonding R^{fc1} and R^{fc2} each other is preferably a fluorinated ethylene group or a fluorinated propylene group.

In the formula (3D), R^{fd} represents a hydrocarbyl group having 1 to 40 carbon atoms and optionally having a heteroatom. The hydrocarbyl group may be a saturated or unsaturated group, and may be any of linear, branched, and cyclic groups. Specific examples thereof include groups same as those exemplified as the hydrocarbyl group represented by R¹¹¹ in the formula (3A′).

Synthesis of the sulfonium salt having the anion represented by the formula (3D) is described in detail in JP 2010-215608 A and JP 2014-133723 A.

Examples of the anion represented by the formula (3D) include anions same as those exemplified as the anions represented by the formula (1D) in JP 2018-197853 A.

Although having no fluorine atom at the α-position of the sulfo group, the photoacid generator having the anion represented by the formula (3D) has sufficient acidity for cleaving the acid-labile group in the base polymer derived from the two trifluoromethyl groups at the β-position. Thus, the photoacid generator having the anion represented by the formula (3D) can be used as the photoacid generator.

### (VI) Quencher

The inventive resist material may further contain a quencher (VI). In the present invention, using the quencher (VI) traps the acid generated in the exposed portion, and the acid diffusion can be inhibited. The quencher (VI) is preferably a weak-acid salt having a structure represented by the following formula (4) and composed of a carboxylate anion and a sulfonium cation. The quencher (IV) can have a function as a catalyst to promote the crosslinking reaction of the crosslinker (II).

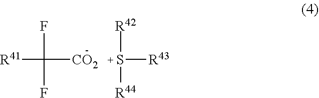

The weak acid generated in the system as above does not contribute to the decomposition of the acetal bond formed by the crosslinker (II), and rather can function as an acid catalyst to promote the crosslinking of a remained unreacted vinyl ether structure.

In the formula (4), R⁴¹ represent a monovalent organic group optionally having a substituent. The organic group optionally has an ether bond, an ester bond, an amide bond, a lactone ring, or a sultone ring. R⁴¹ preferably represents a group having an aromatic hydrocarbon group, and more preferably represents a group having an iodine atom.

In the formula (4), R⁴² to R⁴⁴ each independently represent a monovalent hydrocarbon group having 1 to 20 carbon atoms and optionally having a heteroatom. Any two of R⁴², R⁴³, and R⁴⁴ are optionally bonded each other to form a ring together with the sulfur atom to which R⁴², R⁴³, and R⁴⁴ are bonded.

Examples of anion structures of the quencher (VI) include the following structures, but the anion structure is not limited thereto.

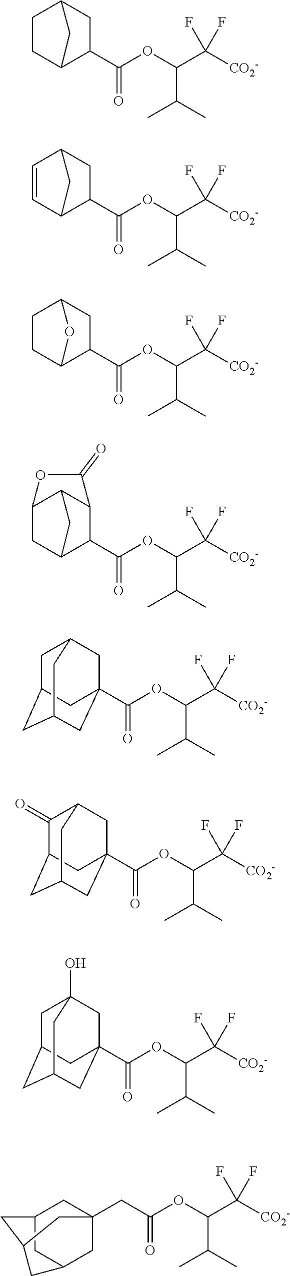

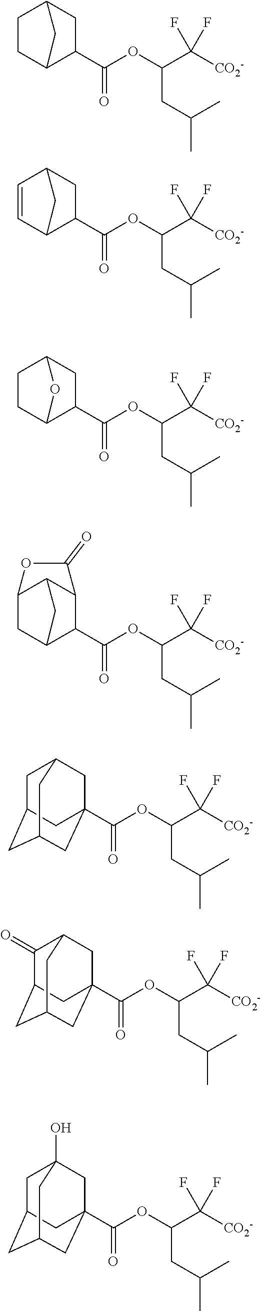

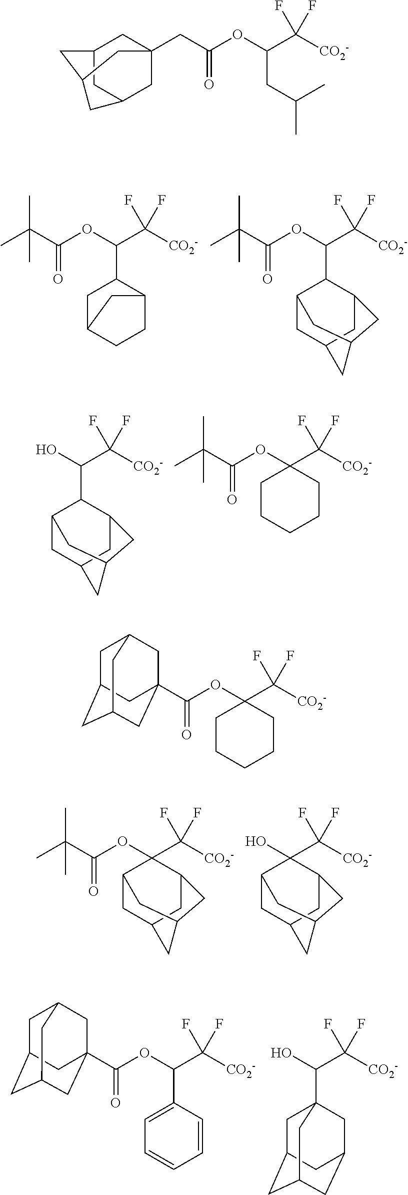

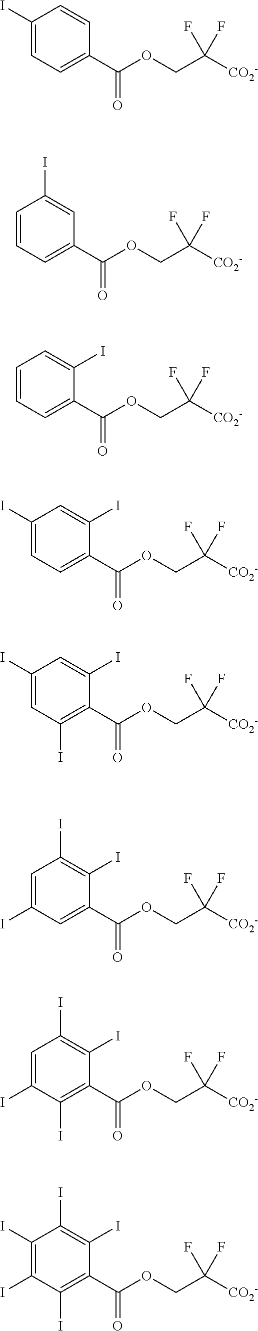

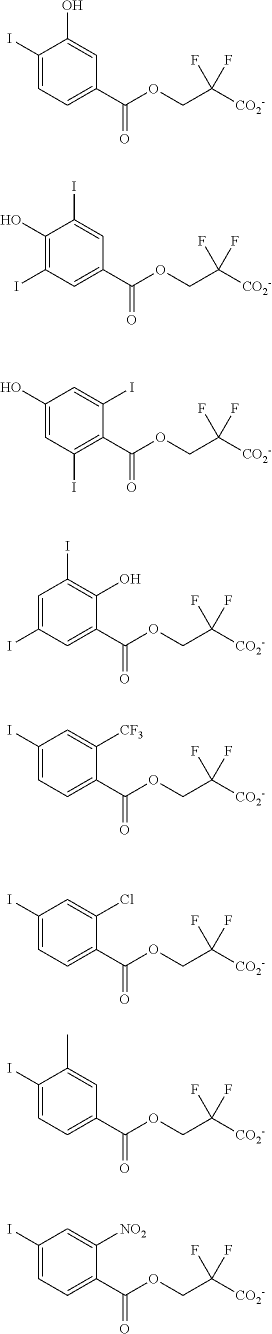

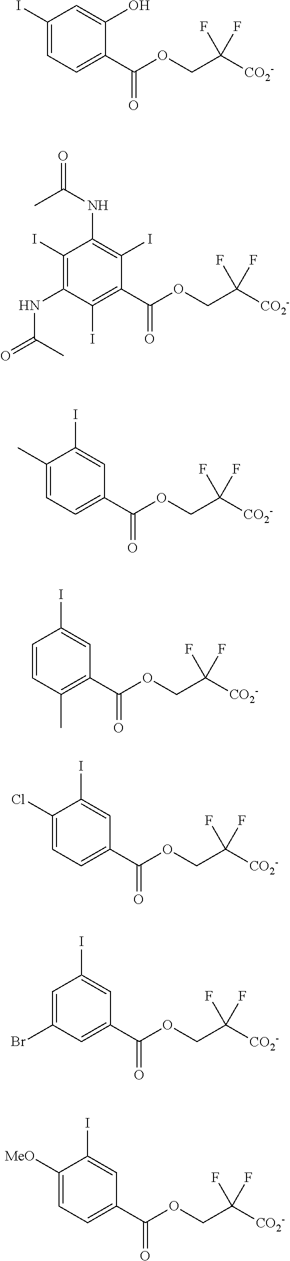

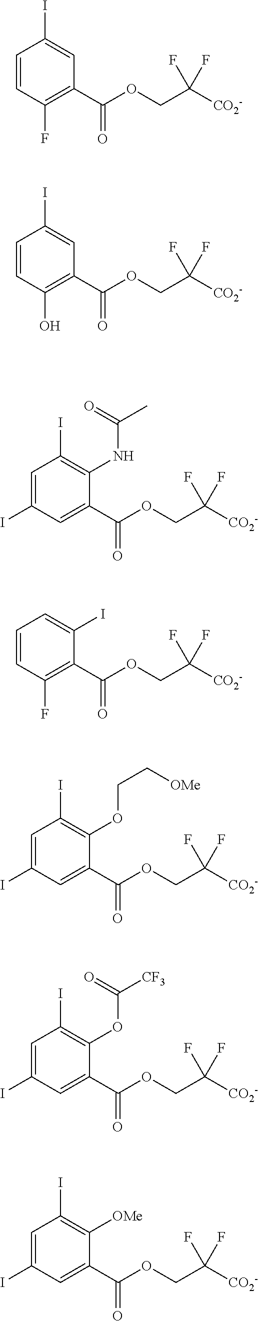

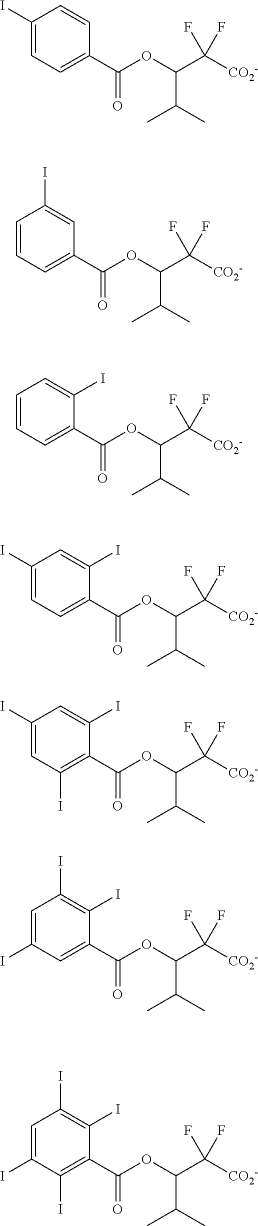

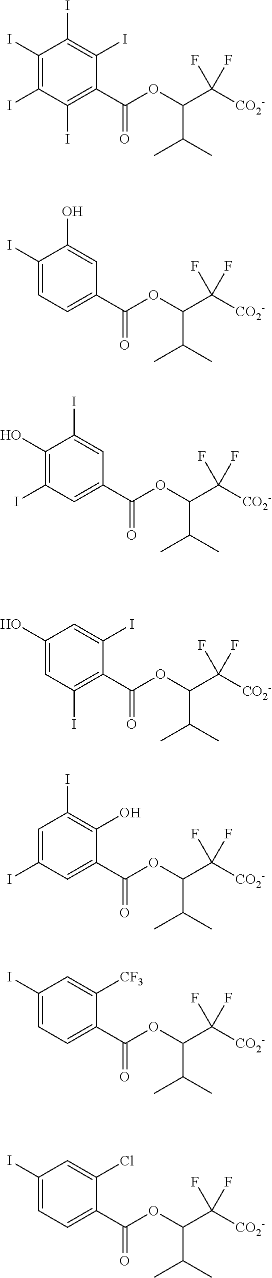

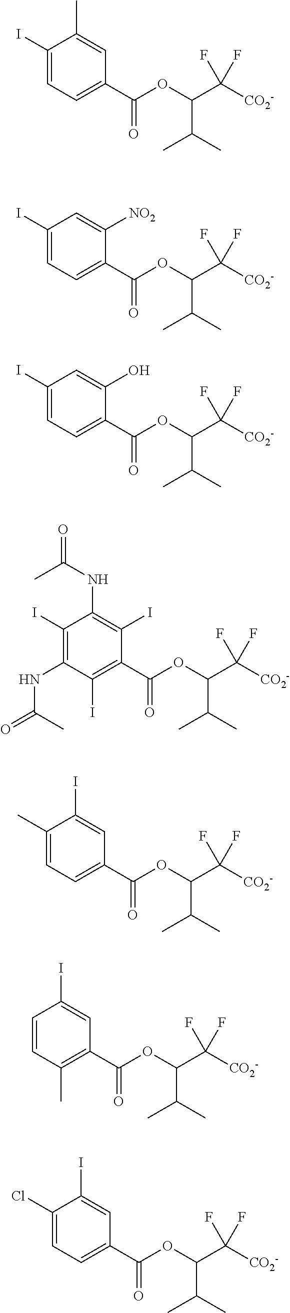

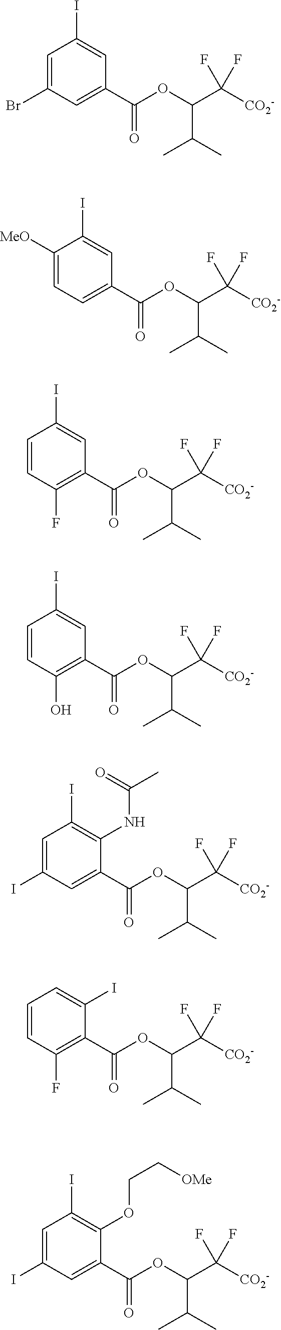

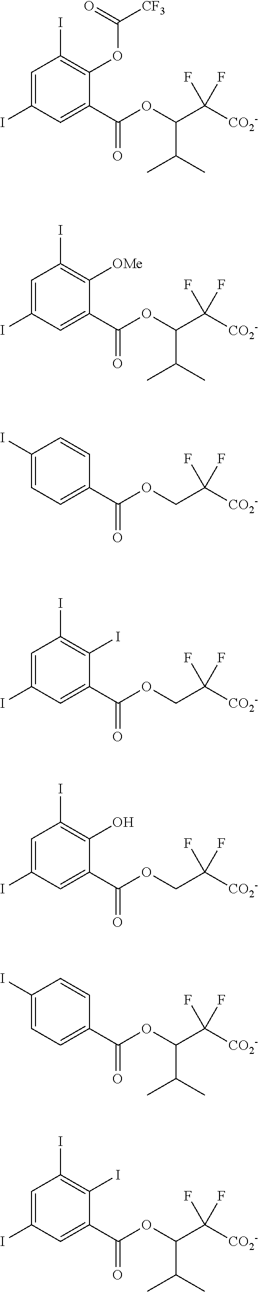

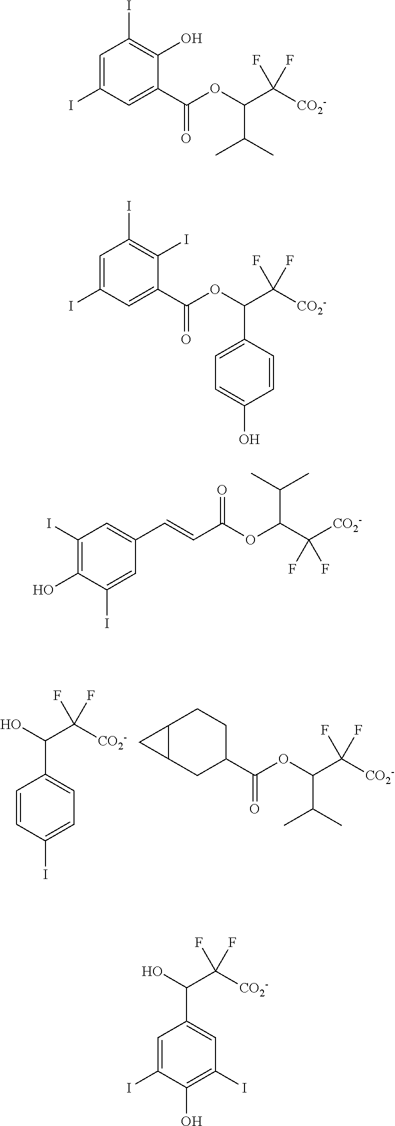

Examples of the cation structure of the quencher (VI) include structures same as those exemplified as a sulfonium cation in a repeating unit (C), described later.

The content of the quencher (VI) in the inventive resist material is preferably 0.1 to 50 parts by mass, and more preferably 1 to 40 parts by mass, relative to 100 parts by mass of the base polymer (P). The quencher (VI) may be used singly, or may be used in combination of two or more kind thereof.

### Surfactant

The inventive resist material may contain a surfactant in addition to the aforementioned components.

Examples of the surfactant include surfactants described in paragraphs [0165] to [0166] of JP 2008-111103 A. Adding the surfactant can further improve or regulate the coatability of the resist material. When the inventive resist material contains the surfactant, the content thereof is preferably 0.0001 to 10 parts by mass relative to 100 parts by mass of the base polymer. The surfactant may be used singly, or may be used in combination of two or more kind thereof.

### Second Aspect

The second aspect of the present invention is a resist material containing the above (Ib), (II), (III), and (IV). The first aspect of the present invention uses the additive-type photoacid generator as the component (V) separately from the base polymer (Ia). On the other hand, in the second aspect of the present invention, the base polymer (Ib) itself has the function of the photoacid generator. Hereinafter, each component will be described in detail.

### (Ib) Base Polymer

The base polymer (P) in the present invention is a polymer having: a repeating unit (A) having a hydroxy group or a carboxy group; and a repeating unit (C) having a structural moiety to be decomposed by irradiation of active ray or radiation to generate an acid.

The repeating unit (A) can be same as the unit described in the above (Ia) base polymer.

The base polymer has the repeating unit (C) having the structural moiety to be decomposed by irradiation of active ray or radiation to generate an acid. Since the repeating unit (C) has high polarity, the polymer having the repeating unit (C) and having a low molecular weight has high solubility in an alkaline developing liquid. Meanwhile, increasing the molecular weight of such an easily soluble component with crosslinking significantly decreases the solubility in the developing liquid. This effect can largely change the dissolution contrast between the crosslinked portion and the non-crosslinked portion.

As the repeating unit (C), a repeating unit (C) represented by the following formula (c) can be used.

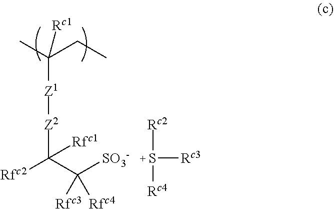

In the formula (c), R^{c1} represents a hydrogen atom or a methyl group.

In the formula (c), Z¹ represents a single bond or an ester bond. Z² represents a single bond, or a divalent organic group having 1 to 25 carbon atoms and optionally having one or more of an ester bond, an ether bond, a lactone ring, an amide bond, a sultone ring, and an iodine atom. The divalent organic group may be any of linear, branched, and cyclic groups. Specific examples thereof include: alkanediyl groups having 1 to 20 carbon atoms, such as a methanediyl group, an ethane-1,1-diyl group, an ethane-1,2-diyl group, a propane-1,2-diyl group, a propane-1,3-diyl group, a propane-2,2-diyl group, a butane-1,2-diyl group, a butane-1,3-diyl group, a butane-1,4-diyl group, a butane-2,2-diyl group, a butane-2,3-diyl group, a 2-methylpropane-1,3-diyl group, a pentane-1,5-diyl group, a hexane-1,6-diyl group, a heptane-1,7-diyl group, an octanone-1,8-diyl group, a nonane-1,9-diyl group, and a decane-1,10-diyl group; cyclic saturated hydrocarbylene groups having 3 to 20 carbon atoms, such as a cyclopentanediyl group, a cyclohexanediyl group, a norbornanediyl group, and an adamantanediyl group; and groups obtained by combining these groups.

In the formula (c), Rf^{c1} to Rf^{c4} each independently represent a hydrogen atom, a fluorine atom, or a trifluoromethyl group, and at least one of Rf^{c1} to Rf^{c4} represents a fluorine atom or a trifluoromethyl group.

In the formula (c), R^{c2} to R^{c4} each independently represent a monovalent hydrocarbon group having 1 to 20 carbon atoms and optionally having a heteroatom.

Any two of R^{c2}, R^{c3}, and R^{c4} are optionally bonded each other to form a ring together with the sulfur atom to which R^{c2}, R^{c3}, and R^{c4} are bonded. In this time, the ring preferably has the following structure.

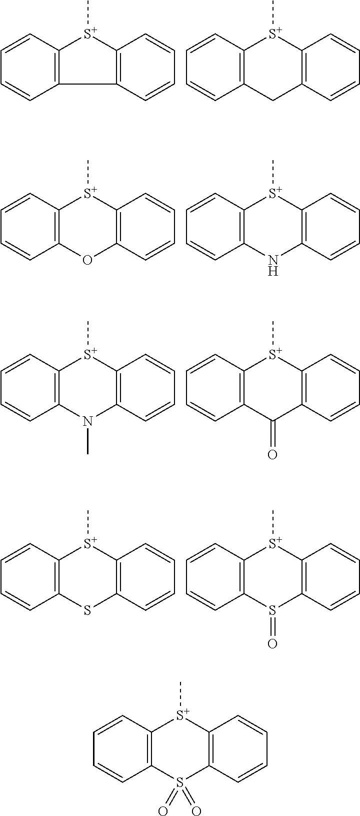

In the formulae, a broken line represents a bond to R^{c4}.

Examples of the anion structure of monomers to yield the repeating unit (C) include the following structures, but the anion structure is not limited thereto.

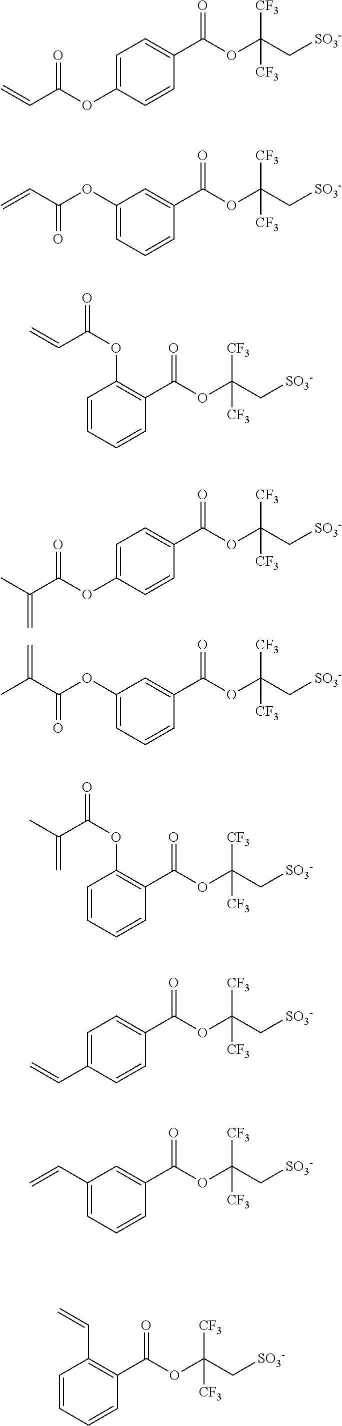

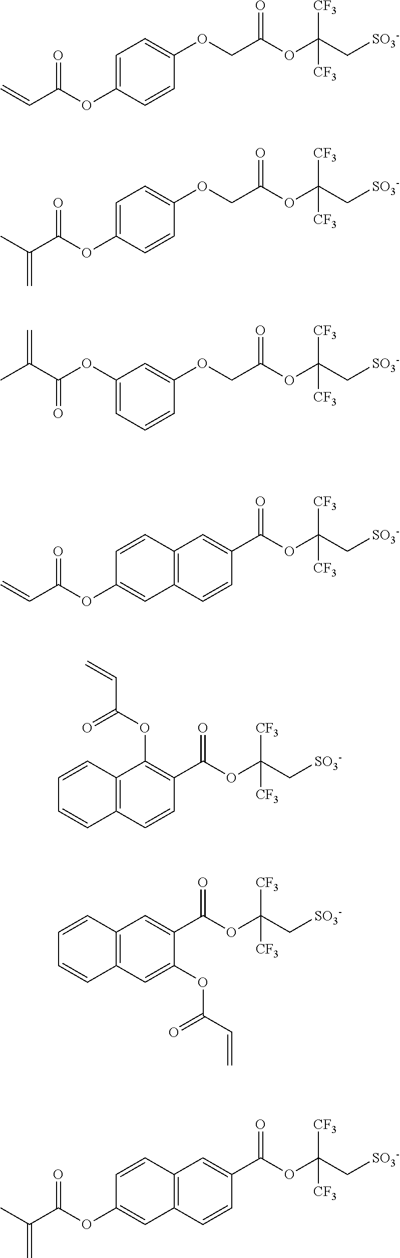

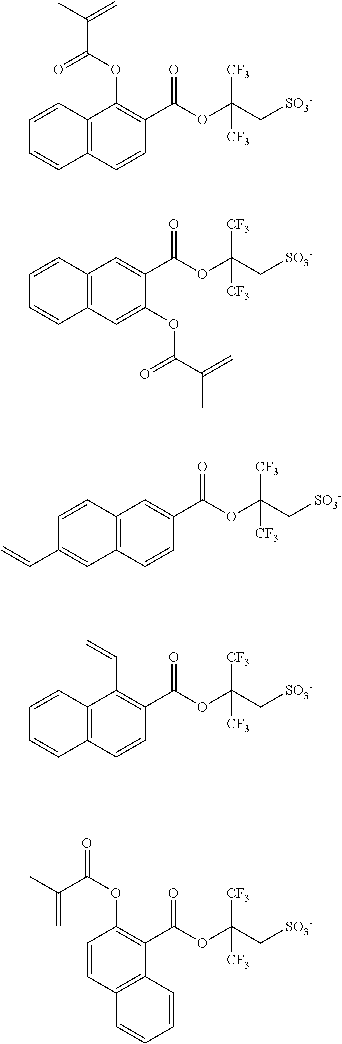

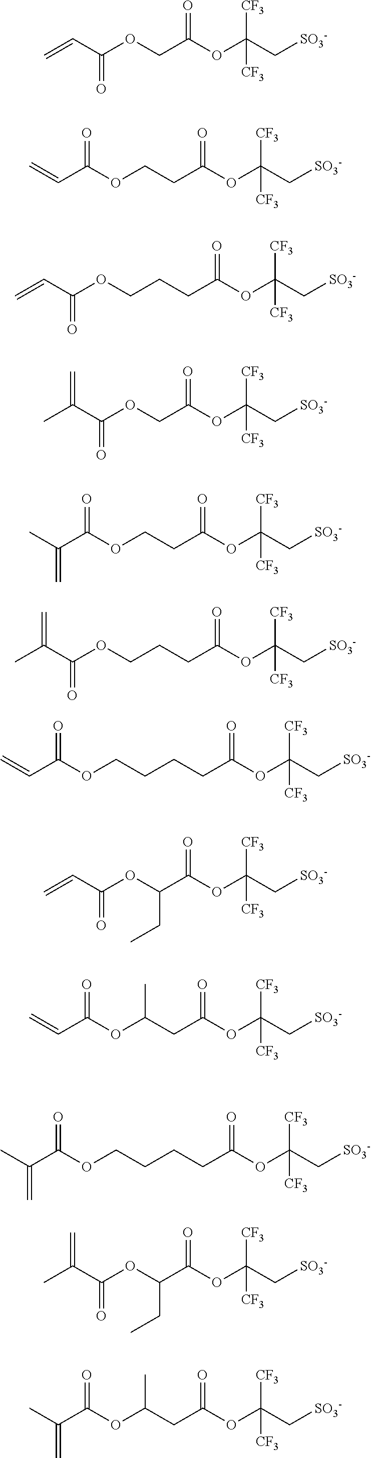

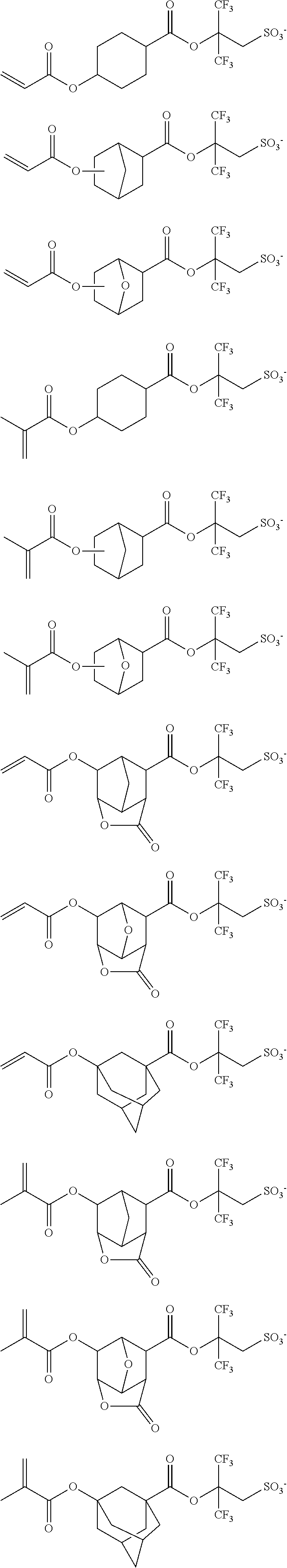

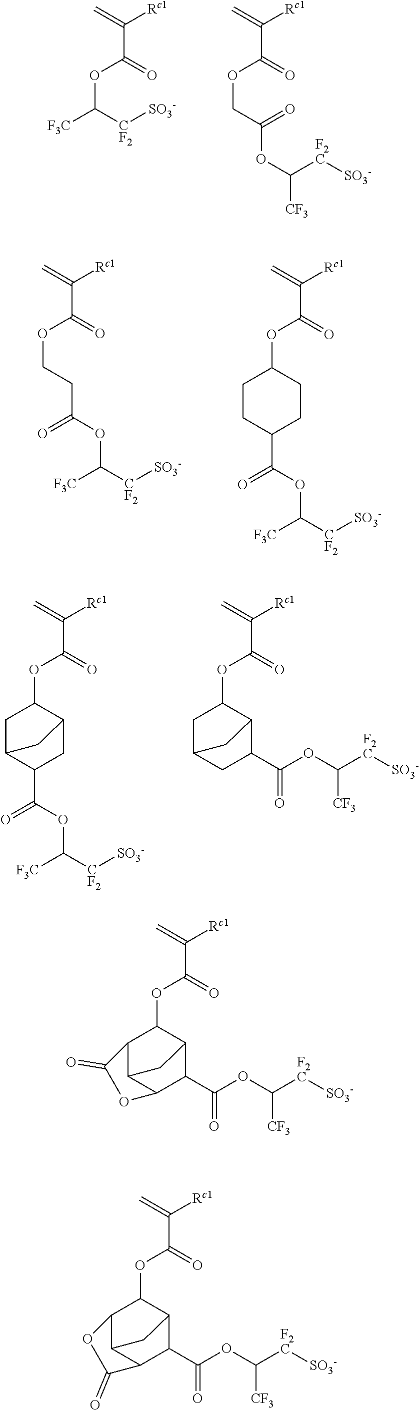

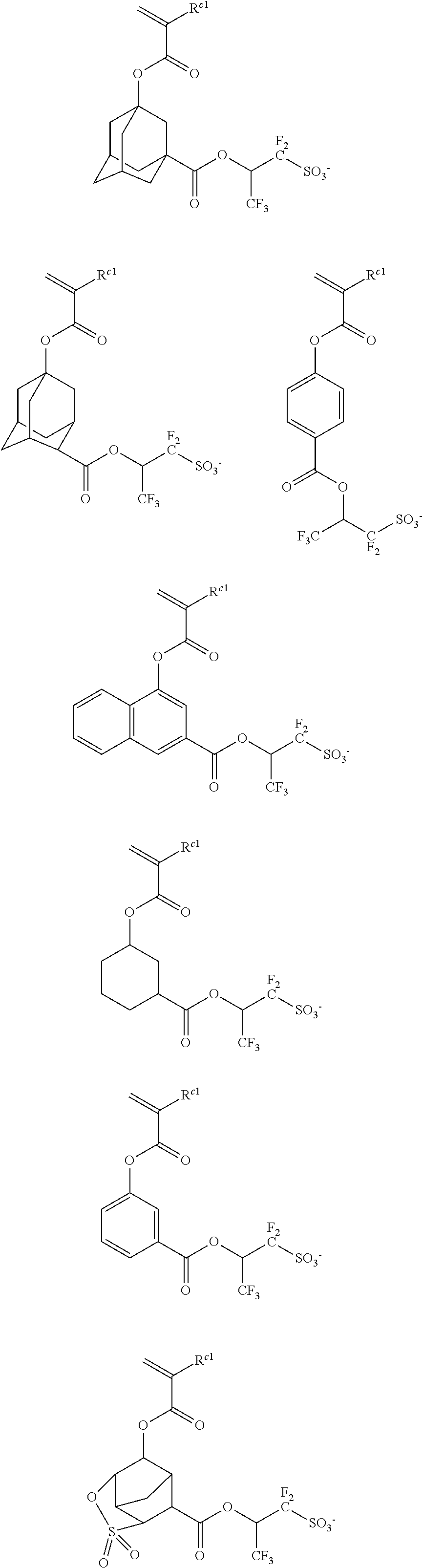

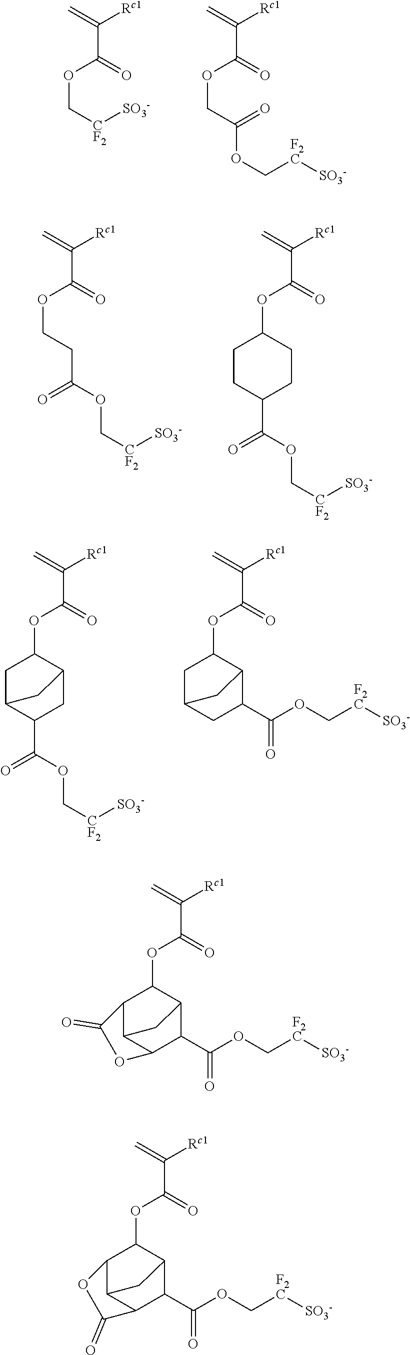

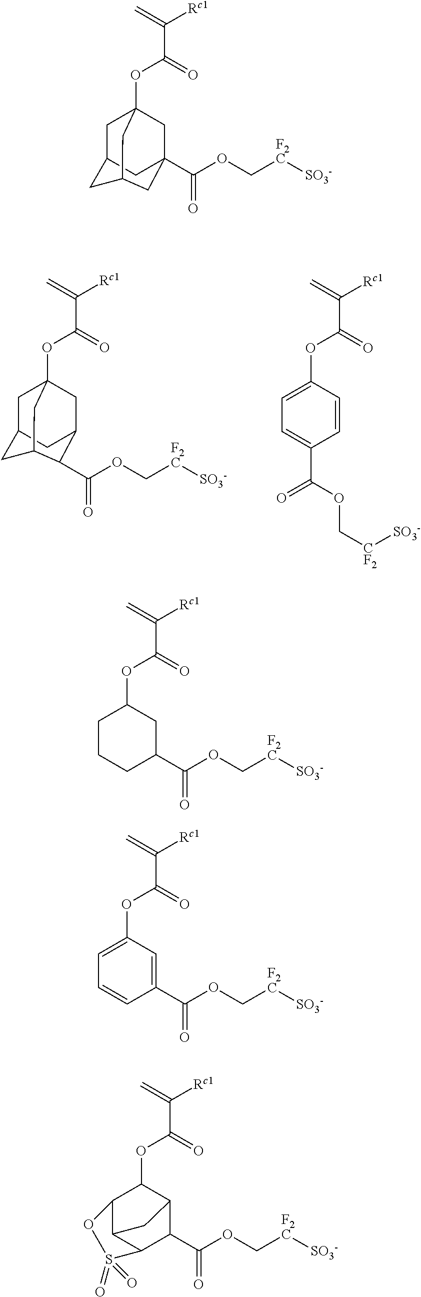

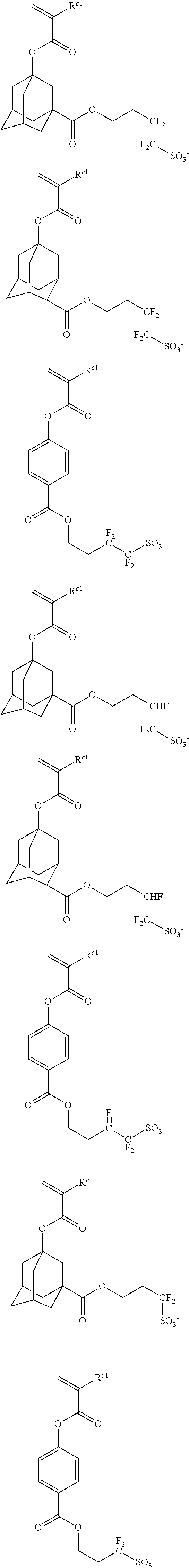

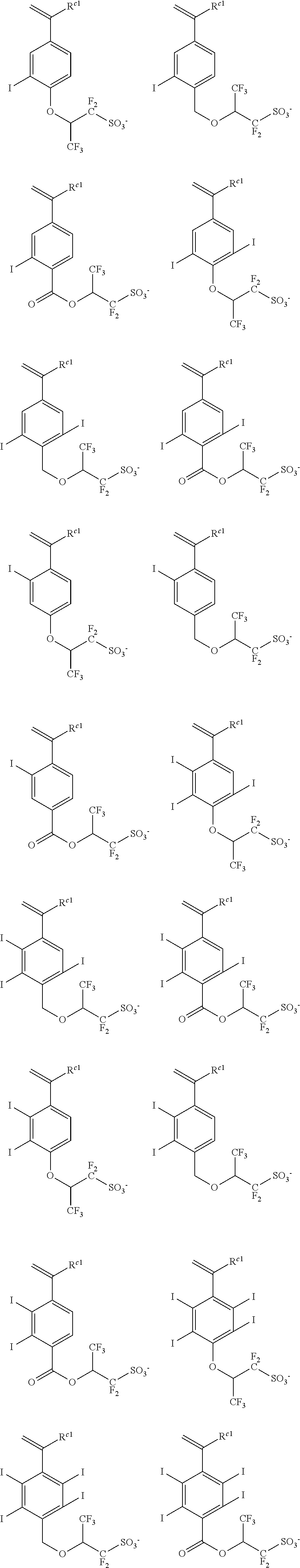

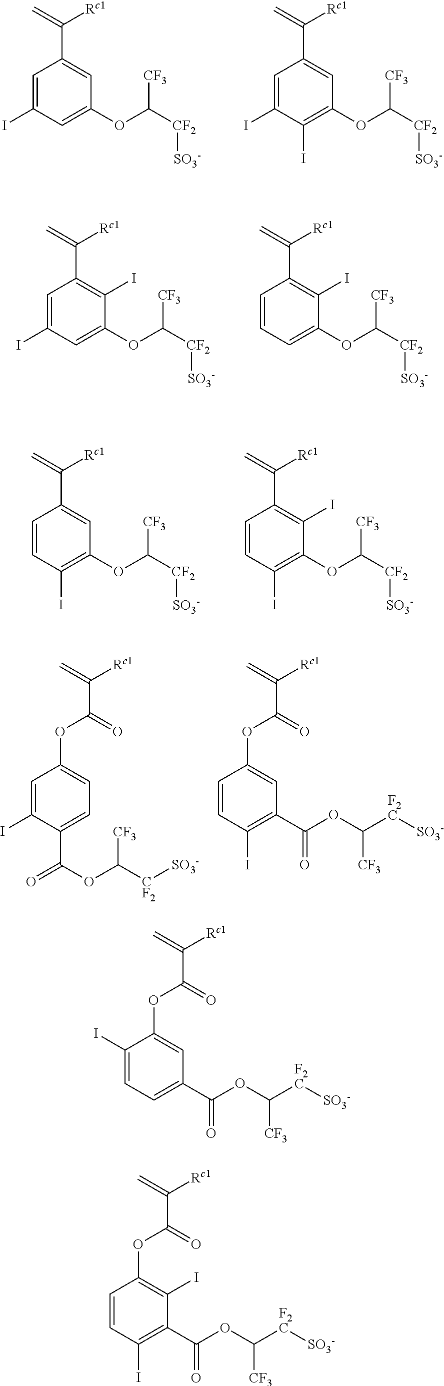

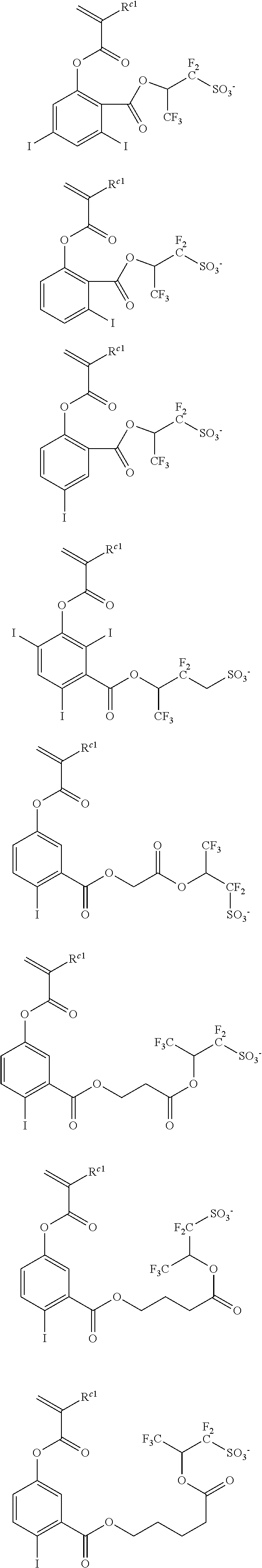

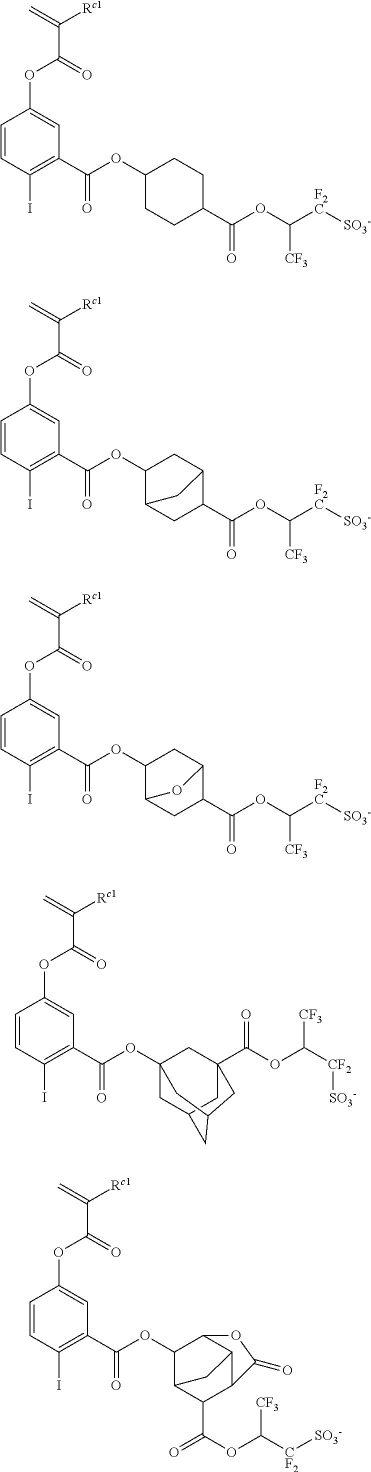

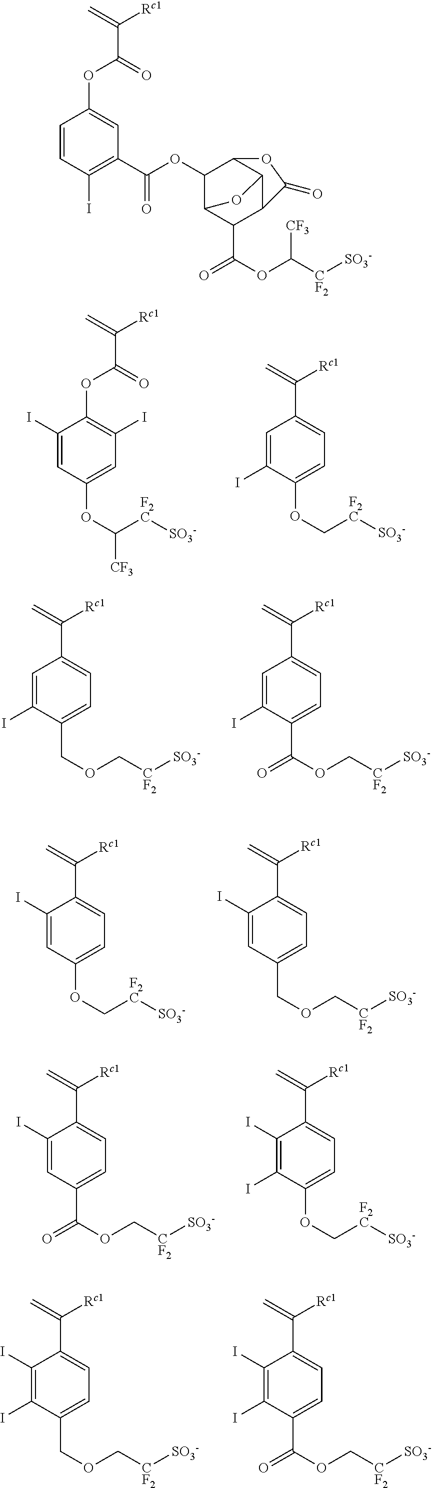

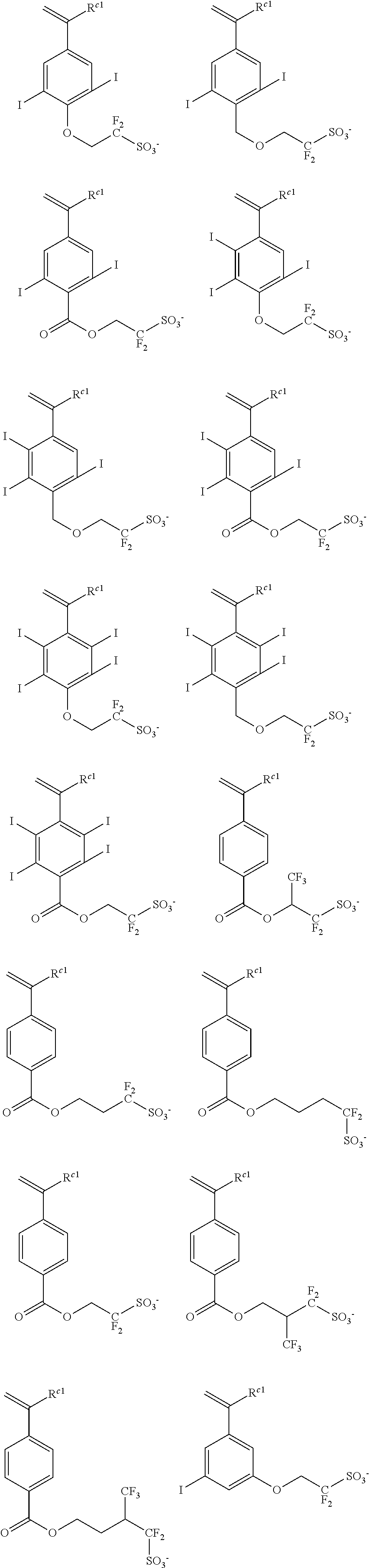

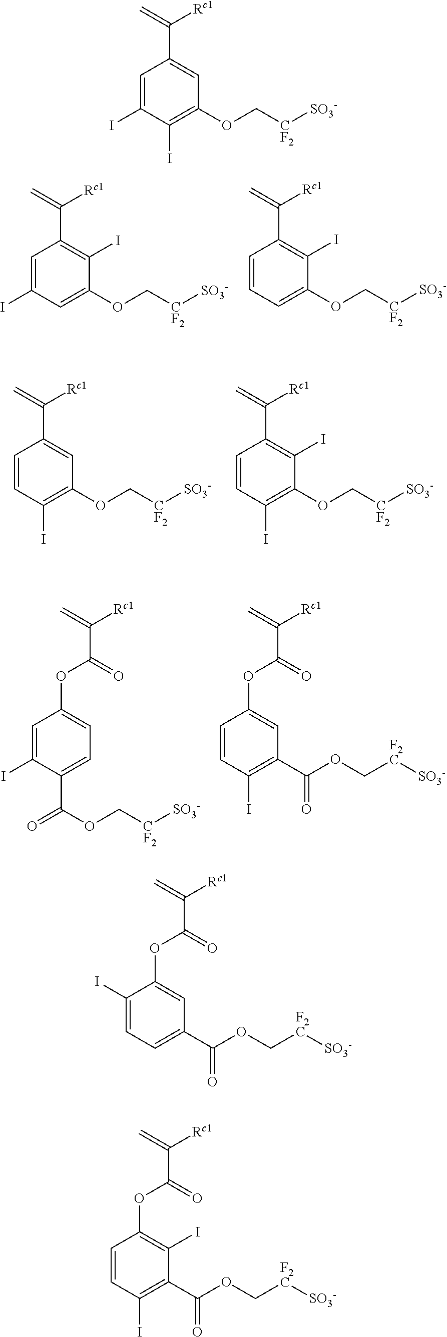

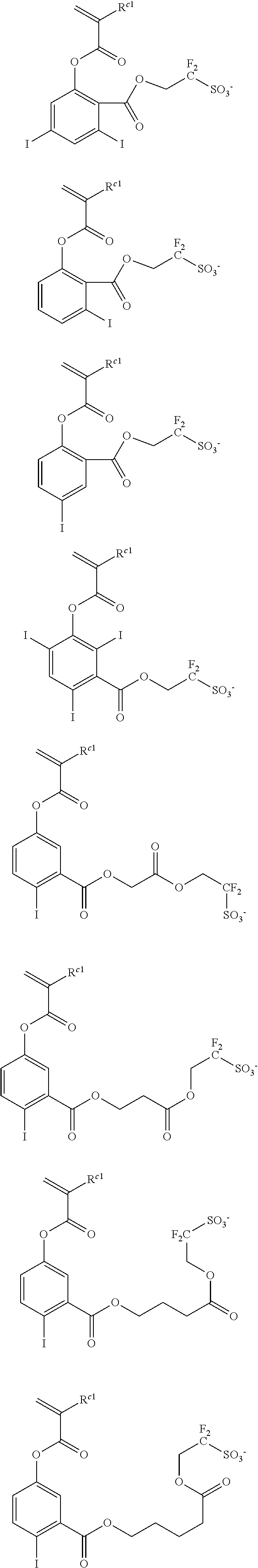

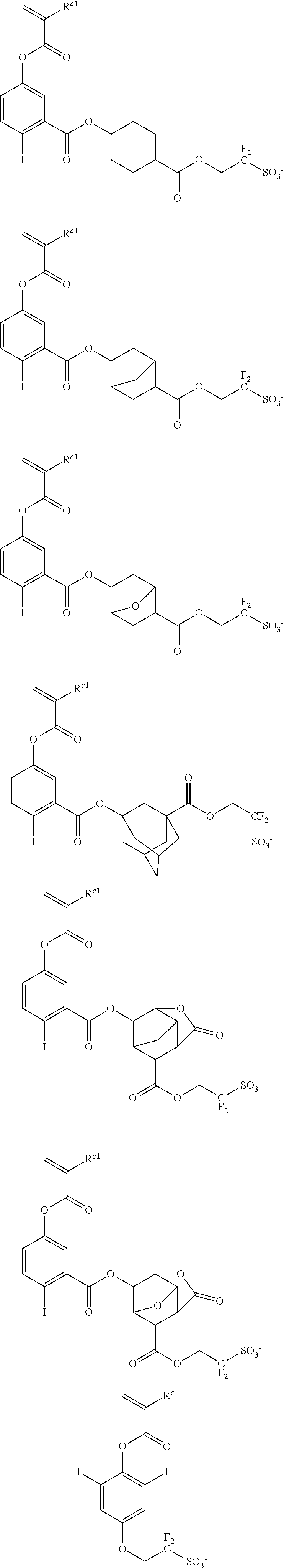

Examples of the sulfonium cation of monomers to yield the repeating unit (C) include the following sulfonium cations, but the sulfonium cation is not limited thereto.

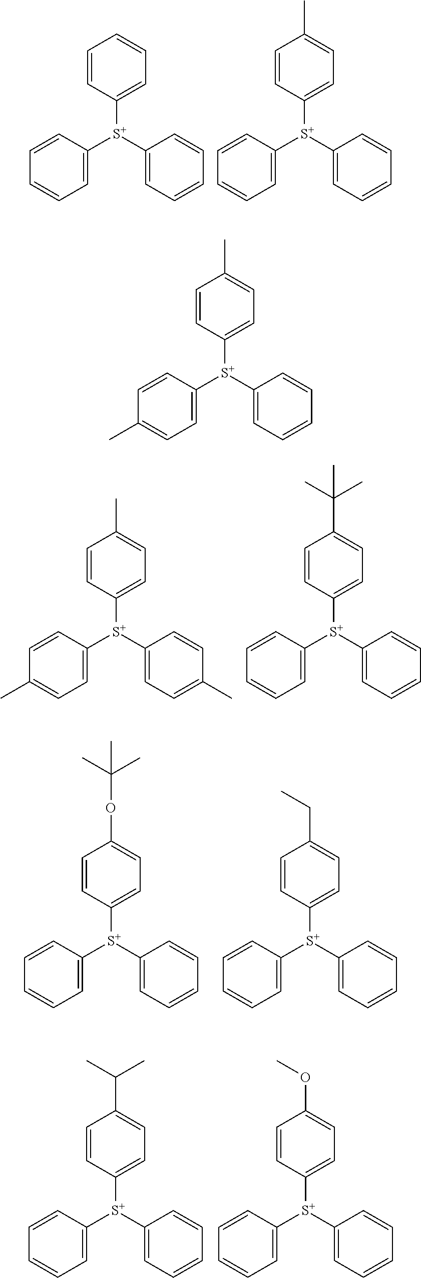

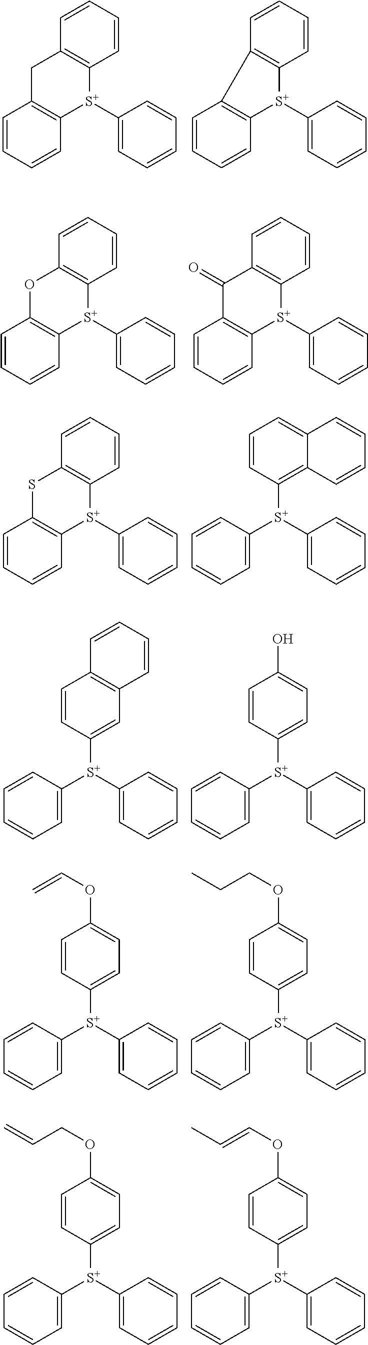

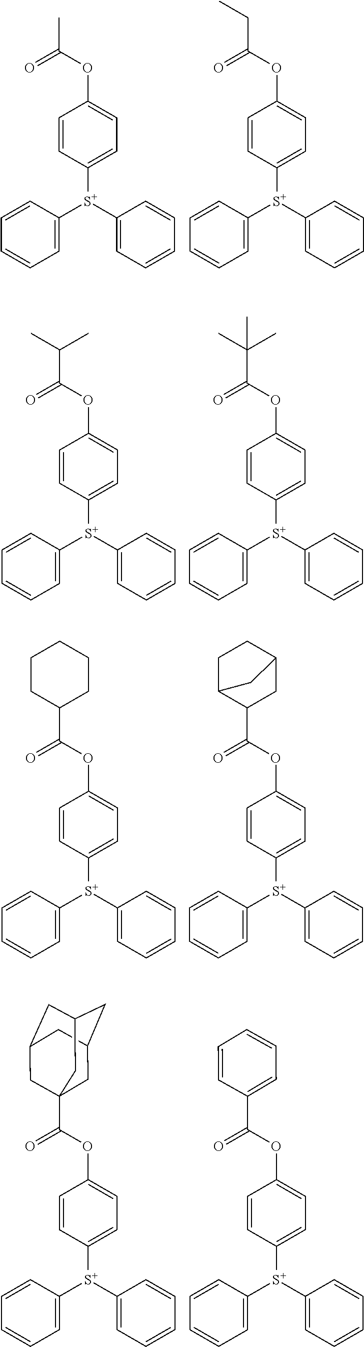

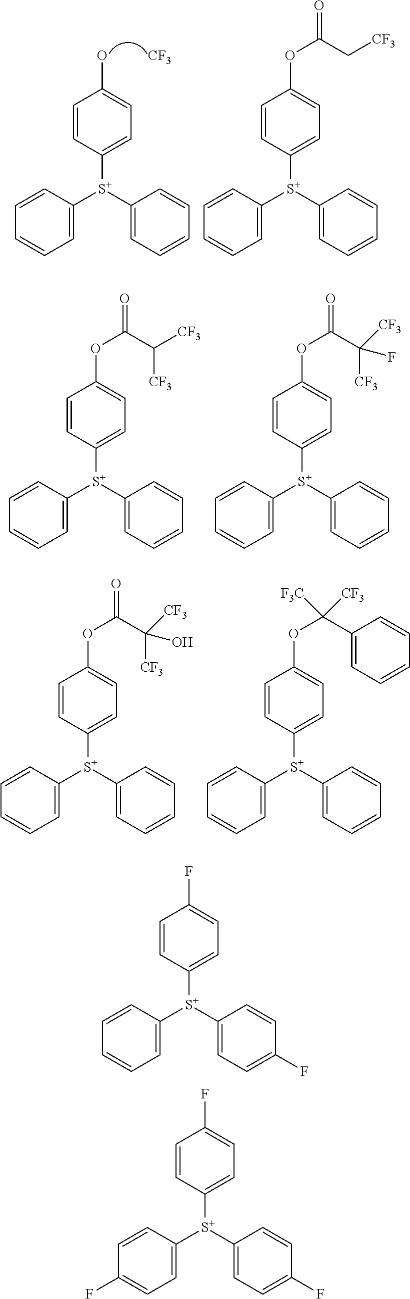

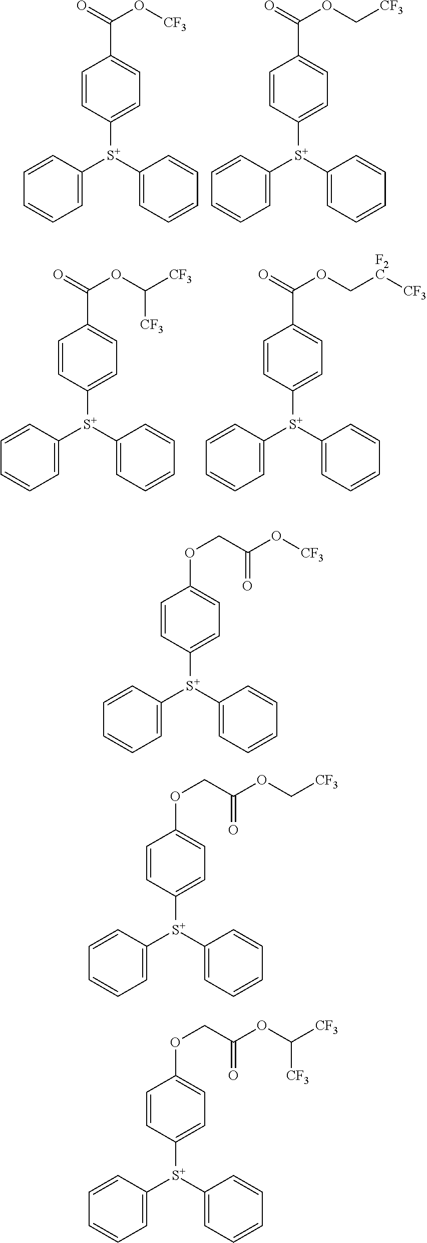

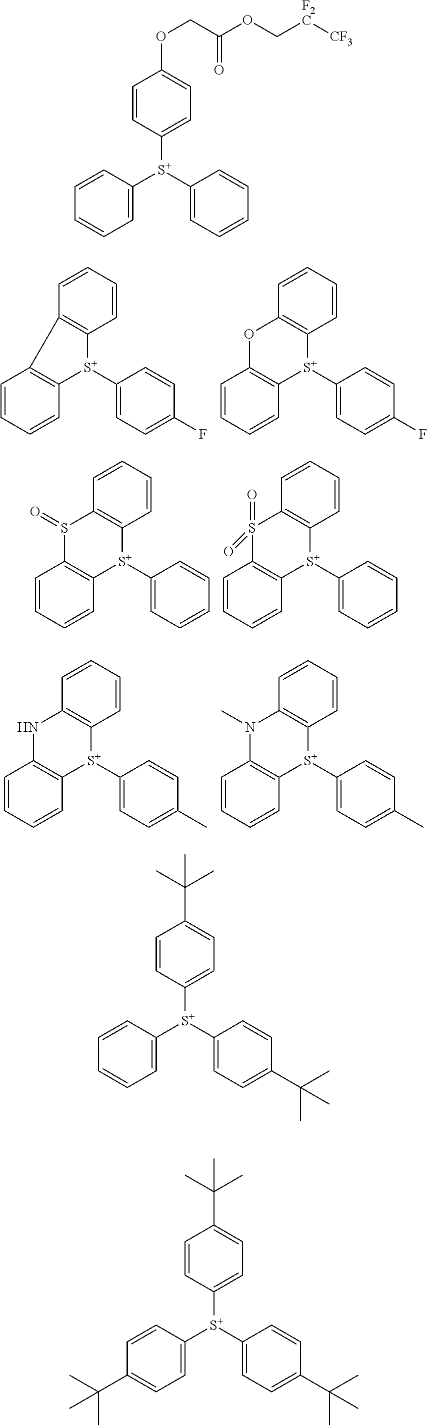

In addition to the repeating units (A) and (C), the base polymer (P) preferably has a repeating unit (B) in which the hydrogen atom of the carboxy group in the repeating unit (A) is substituted with an acid-labile group. The repeating unit (B) can be same as the unit described in the above (Ia) base polymer.

The content of the repeating unit (C) contained in the base polymer (P) is preferably 50 mol % or less, and more preferably 30 mol % or less and 5 mol % or more.

### (II) Crosslinker

The crosslinker (II) can be same as the crosslinker described in the above first aspect.

### (III) Thermal Acid Generator

The thermal acid generator (III) can be same as the thermal acid generator described in the above first aspect.

### (IV) Organic Solvent

The organic solvent (IV) can be same as the organic solvent described in the above first aspect.

### (V) Component to be Decomposed by Irradiation of Active Ray or Radiation to Generate Acid

In the resist material of the second aspect of the present invention, an additive-type photoacid generator may be blended as the component (V). The component (V) can be same as the component described in the above first aspect.

### (VI) Quencher

In the resist material of the second aspect of the present invention, a quencher may be blended as the component (VI). The component (VI) can be same as the component described in the above first aspect.

### Surfactant

In the resist material of the second aspect of the present invention, a surfactant may be blended. The surfactant can be same as the surfactant described in the above first aspect.

### Patterning Process

The inventive resist material is suitable as a positive-type resist material, and when the inventive resist material is used in each integrated circuit manufacturing, a known lithography technique can be applied. Example of the patterning process include a method comprising:
(i) a step of forming a resist film by applying a resist material on a substrate using the aforementioned resist material;
(ii) a step of exposing the resist film with a high-energy ray; and
(iii) a step of developing the exposed resist film using a developing liquid.

### Step (i)

First, the inventive resist material is applied on a substrate for integrated circuit manufacturing (such as Si, SiO₂, SiN, SiON, TiN, WSi, BPSG, SOG, and an organic anti-reflective film) or a substrate for mask circuit manufacturing (such as Cr, CrO, CrON, MoSi₂, and SiO₂) by an appropriate coating method such as spin coating, roll coating, flow coating, dip coating, spray coating, and doctor coating so that the coating film thickness is 0.01 to 2 μm. This coating film is prebaked on a hot plate for 30 seconds to 20 minutes to form a resist film. To efficiently proceed the crosslinking reaction with the crosslinker, the temperature of the prebaking is preferably 130° C. or higher.

### Step (ii)

Then, the resist film is exposed by using high-energy ray. Examples of the high-energy ray include ultraviolet ray, far ultraviolet ray, EB, EUV having a wave length of 3 to 15 nm, X-ray, soft X-ray, excimer laser light, γ-ray, and synchrotron radiation. When ultraviolet ray, far ultraviolet ray, EUV, X-ray, soft X-ray, excimer laser light, γ-ray, synchrotron radiation, etc. are used as the high-energy ray, irradiation is performed directly or using a mask for forming a target pattern so that the exposure dose is preferably approximately 1 to 200 mJ/cm², more preferably approximately 10 to 100 mJ/cm². When EB is used as the high-energy ray, writing is performed directly or by using a mask for forming a target pattern so that the exposure dose is preferably approximately 0.1 to 100 μC/cm², more preferably approximately 0.5 to 50 μC/cm². The inventive positive-type resist material is suitable for fine pattering with, among the high-energy ray, KrF excimer laser light, ArF excimer laser light, EB, EUV, X-ray, soft X-ray, γ-ray, and synchrotron radiation, and particularly suitable for fine patterning with EB or EUV.

After the exposure, post exposure baking (PEB) may be performed on a hot plate or in an oven preferably at 50 to 150° C. for 10 seconds to 30 minutes, more preferably at 60 to 120° C. for 30 seconds to 20 minutes. PEB is a heating step performed after the exposure of the resist film.

Step (iii)

After the exposure or the PEB, the exposed resist film is developed by a common method such as a dip method, a puddle method, and a spray method for 3 seconds to 3 minutes, preferably 5 seconds to 2 minutes. In the common method, used are a developing liquid of a 0.1 to 10 mass %, preferably 2 to 5 mass %, of alkaline aqueous solution such as tetramethylammonium hydroxide (TMAH), tetraethylammonium hydroxide (TEAH), tetrapropylammonium hydroxide (TPAH), and tetrabutylammonium hydroxide (TBAH). The development dissolves the light-irradiated portion in the developing liquid, and does not dissolve the unexposed portion to form a target positive-type pattern on the substrate.

Using the resist material, the development can also be performed with organic solvent development. Examples of the developing liquid used in this case include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate. These organic solvents can be used singly, or used with mixing two or more kinds thereof.

When the development is finished, rinsing is performed. A preferable solvent for a rinsing liquid mixes with the developing liquid and does not dissolve the resist film. As such a solvent, alcohols having 3 to 10 carbon atoms, ether compounds having 8 to 12 carbon atoms, alkanes, alkenes, and alkynes having 6 to 12 carbon atoms, and aromatic solvents are preferably used.

Specific examples of the alcohols having 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol.

Examples of the ether compounds having 8 to 12 carbon atoms include di-n-butyl ether, diisobutyl ether, di-sec-butyl ether, di-n-pentyl ether, diisopentyl ether, di-sec-pentyl ether, di-tert-pentyl ether, and di-n-hexyl ether.

Examples of the alkanes having 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Examples of the alkenes having 6 to 12 carbon atoms include hexene, heptene, octene, cyclohexene, methylcyclohexene, dimethylcyclohexene, cycloheptene, and cyclooctene. Examples of the alkynes having 6 to 12 carbon atoms include hexyne, heptyne, and octyne.

Examples of the aromatic solvents include toluene, xylene, ethylbenzene, isopropylbenzene, tert-butylbenzene, and mesitylene.

Rinsing can reduce collapse of the resist pattern and occurrence of defects. Rinsing is not essential, and no rinsing can reduce a use amount of the solvent.

A hole pattern or trench pattern after the development can be shrunk by thermal flow, RELACS technology, or DSA technology. A shrinking agent is applied on the hole pattern, and during a baking, an acid catalyst diffuses from the resist film to cause the crosslinking of the shrinking agent on the resist film surface, and the shrinking agent adheres to the side wall of the hole pattern. The baking temperature is preferably 70 to 180° C., and more preferably 80 to 170° C. The baking time is preferably 10 to 300 seconds. The extra shrinking agent is removed to shrink the hole pattern.

### EXAMPLE

Hereinafter, the present invention will be specifically described by using Examples and Comparative Examples, but the present invention is not limited thereto.

### Preparation and Evaluation of Resist Material

### (1) Preparation of Resist Material

Into a solvent dissolving 50 ppm of PolyFox PF-636, which was a surfactant manufactured by OMNOVA Solutions Inc., each component was dissolved at the composition shown in Tables 1 and 2, and the solution was filtered with a filter with 0.2 μm in size to prepare each of resist materials (for Examples: R1 to R17, for Comparative Examples: cR1 to cR13). Tables 1 and 2 show the content of each of the resist material.

The contents of each component in Table 1 and Table 2 are as follows.

### Organic Solvent:

PGMEA (propylene glycol monomethyl ether acetate)

DAA (diacetone alcohol)

EL (ethyl lactate)

Base polymer: P-1 to P-11, cP-1, and cP-2

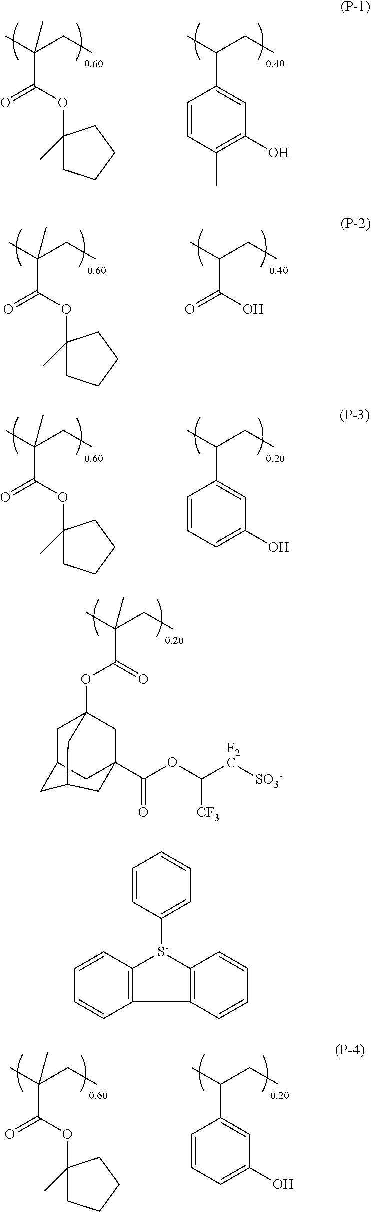

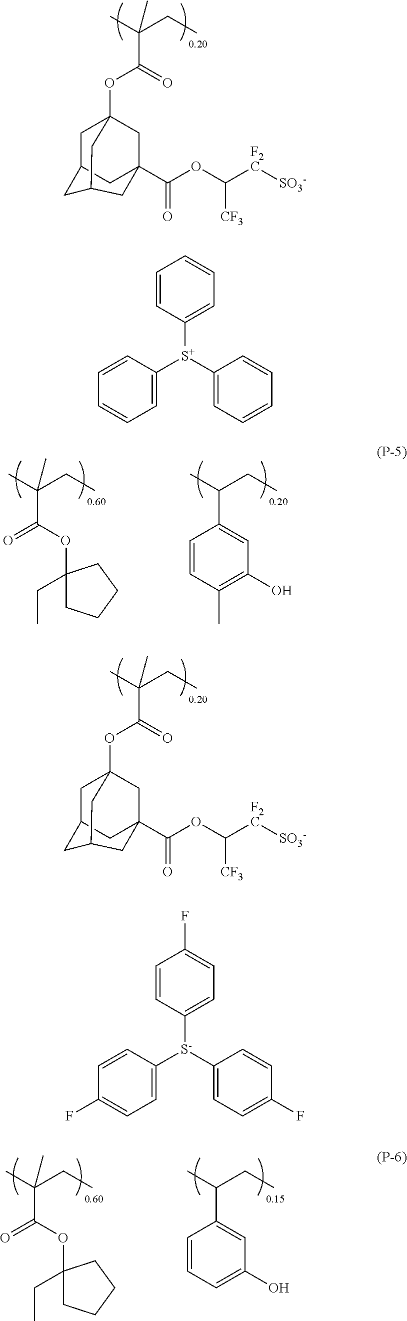

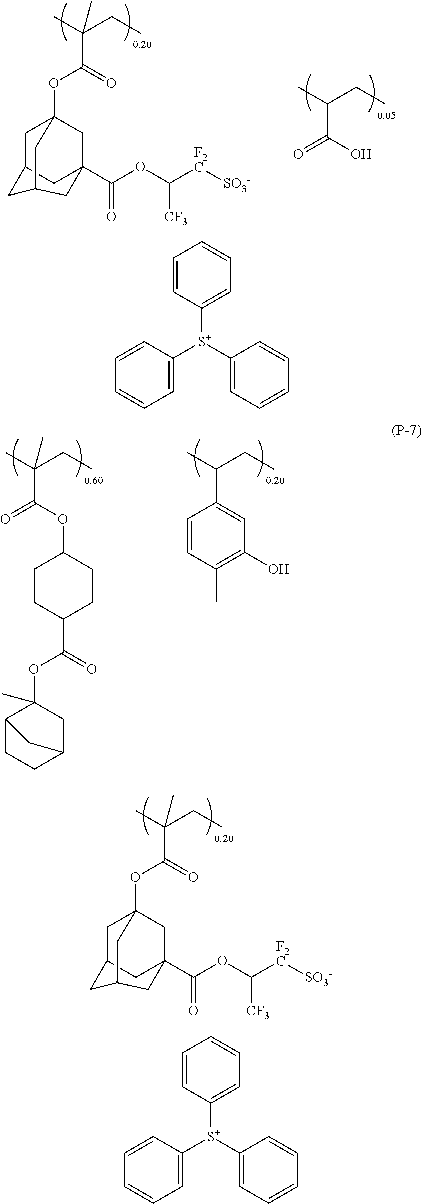

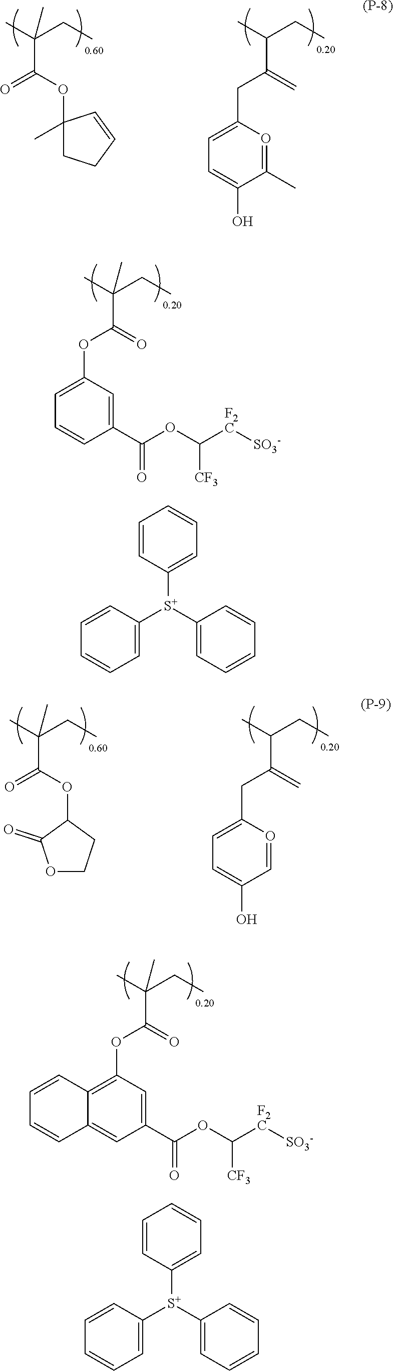

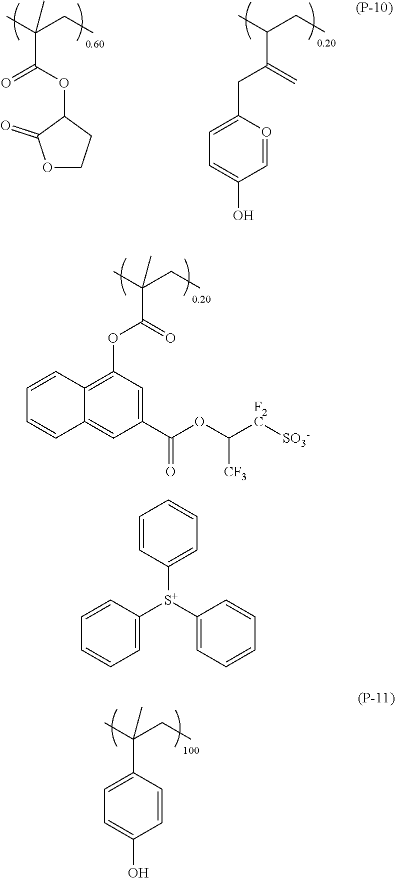

Photoacid generator: PAG-1 to PAG-5

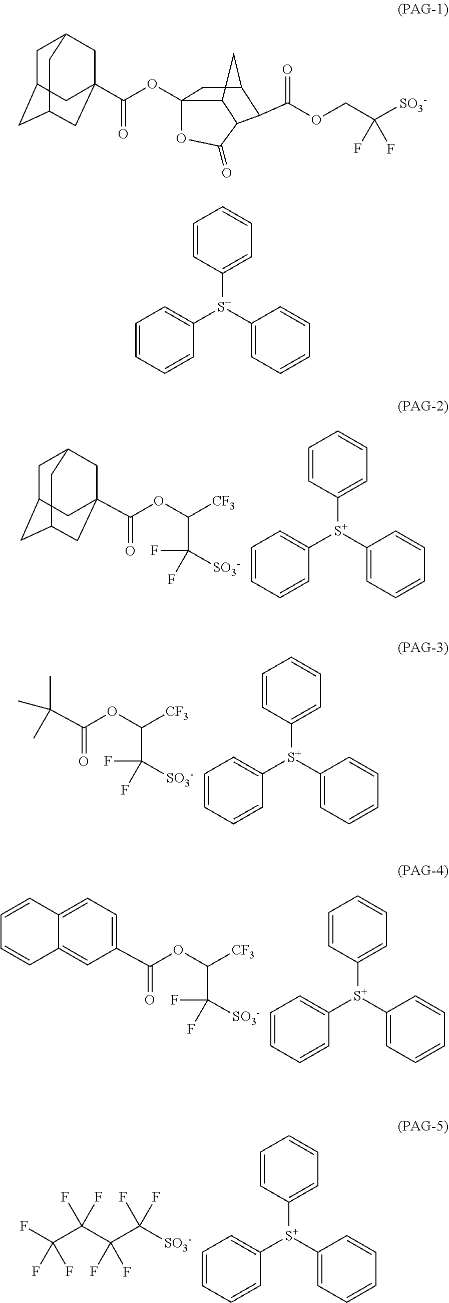

### Quencher: Q-1 to Q-5

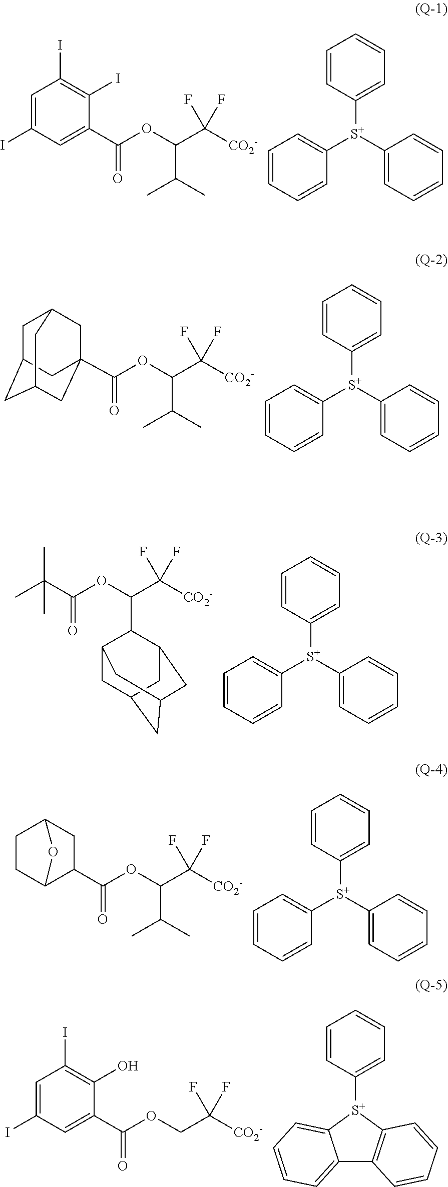

### Crosslinker: X-1, X-2, X-3, and X-4

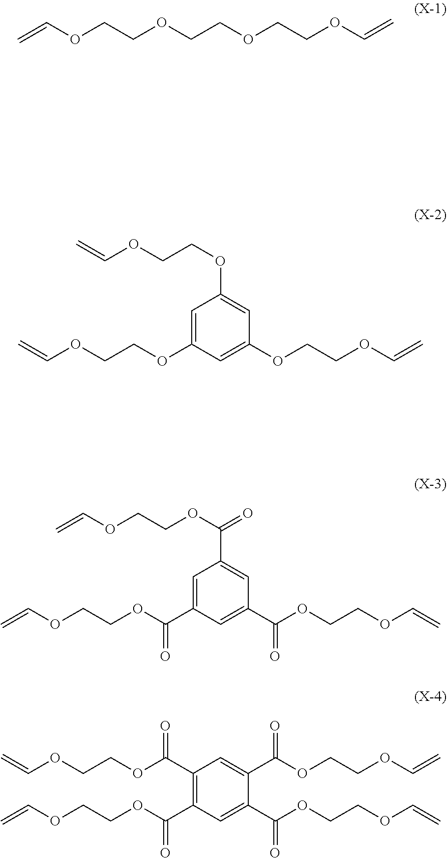

Thermal acid generator: T-1 to T-7 and cT-1 to cT-5

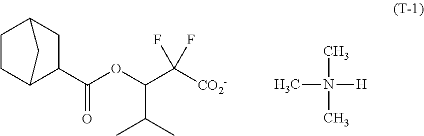

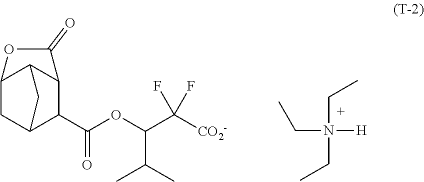

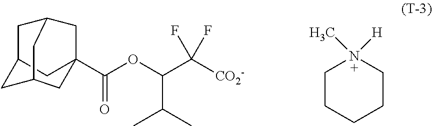

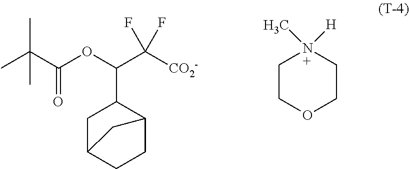

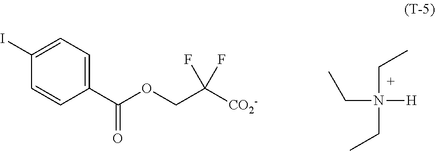

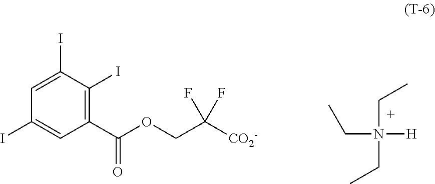

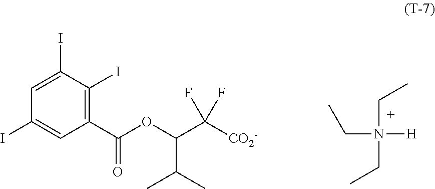

Other additives: A-1, A-2, A-3, and A-4

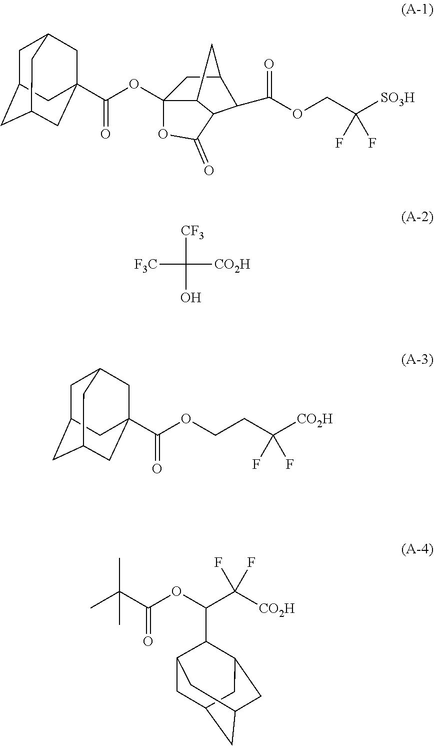 [SMILES: O=C(OCC(F)(F)S(=O)(=O)O)C1C2CC3C1C(=O)OC3(OC(=O)C13CC4CC(CC(C4)C1)C3)C2 ; O=C(O)C(O)(C(F)(F)F)C(F)(F)F ; O=C(O)C(F)(F)CCOC(=O)C12CC3CC(CC(C3)C1)C2 ; CC(C)(C)C(=O)OC(C1C2CC3CC(C2)CC1C3)C(F)(F)C(=O)O]

TABLE 1

| | | Photo- | | | Thermal | | |
|---|---|---|---|---|---|---|---|
| | Base | acid | | Cross- | acid | | |
| | polymer | generator | Quencher | linker | generator | Additive | |
| Resist | (parts | (parts | (parts | (parts | (parts | (parts | |
| composition | by mass) | by mass) | by mass) | by mass) | by mass) | by mass) | Organic solvent |
| R1 | P-1 | PAG-1 | Q-1 | X-1 | T-1 | — | PGMEA/DAA/EL |
| | (80) | (5) | (14) | (13) | (5) | | |
| R2 | P-1 | PAG-2 | Q-2 | X-2 | T-2 | — | PGMEA/DAA/EL |
| | (80) | (5) | (14) | (13) | (5) | | |
| R3 | P-1 | PAG-3 | Q-3 | X-3 | T-3 | — | PGMEA/DAA/EL |
| | (80) | (5) | (14) | (13) | (5) | | |
| R4 | P-1 | PAG-4 | Q-4 | X-4 | T-4 | — | PGMEA/DAA/EL |
| | (80) | (5) | (14) | (13) | (5) | | |
| R5 | P-1 | PAG-5 | Q-5 | X-4 | T-5 | — | PGMEA/DAA/EL |
| | (80) | (5) | (14) | (13) | (5) | | |
| R6 | P-1 | PAG-1 | Q-1 | X-1 | T-6 | — | PGMEA/DAA/EL |
| | (80) | (5) | (14) | (13) | (5) | | |
| R7 | P-1 | PAG-1 | Q-1 | X-1 | T-7 | — | PGMEA/DAA/EL |
| | (80) | (5) | (14) | (13) | (5) | | |
| R8 | P-2 | PAG-2 | Q-2 | X-2 | T-2 | — | PGMEA/DAA/EL |
| | (80) | (5) | (14) | (13) | (5) | | |
| R9 | P-3 | — | Q-3 | X-3 | T-3 | — | PGMEA/DAA/EL |
| | (80) | | (14) | (13) | (5) | | |
| R10 | P-4 | — | Q-4 | X-4 | T-4 | — | PGMEA/DAA/EL |
| | (80) | | (14) | (13) | (5) | | |
| R11 | P-5 | — | Q-5 | X-1 | T-5 | — | PGMEA/DAA/EL |
| | (80) | | (14) | (13) | (5) | | |
| R12 | P-6 | — | Q-1 | X-2 | T-6 | — | PGMEA/DAA/EL |
| | (80) | | (14) | (13) | (5) | | |
| R13 | P-7 | — | Q-2 | X-3 | T-7 | — | PGMEA/DAA/EL |
| | (80) | | (14) | (13) | (5) | | |
| R14 | P-8 | — | Q-3 | X-4 | T-1 | — | PGMEA/DAA/EL |
| | (80) | | (14) | (13) | (5) | | |
| R15 | P-9 | — | Q-4 | X-1 | T-2 | — | PGMEA/DAA/EL |
| | (80) | | (14) | (13) | (5) | | |
| R16 | P-10 | — | Q-5 | X-2 | T-3 | — | PGMEA/DAA/EL |
| | (80) | | (14) | (13) | (5) | | |
| R17 | P-11 | PAG-1 | Q-1 | X-3 | T-4 | — | PGMEA/DAA/EL |
| | (80) | (5) | (14) | (13) | (5) | | |

TABLE 2

| | | Photo- | | | Thermal | | |
|---|---|---|---|---|---|---|---|
| | Base | acid | | Cross- | acid | | |
| | polymer | generator | Quencher | linker | generator | Additive | |
| Resist | (parts | (parts | (parts | (parts | (parts | (parts | |
| composition | by mass) | by mass) | by mass) | by mass) | by mass) | by mass) | Organic solvent |
| cR1 | P-3 | — | Q-3 | X-3 | — | A-1 | PGMEA/DAA/EL |
| | (80) | | (14) | (13) | | (1) | |
| cR2 | P-3 | — | Q-3 | X-3 | — | A-2 | PGMEA/DAA/EL |
| | (80) | | (14) | (13) | | (1) | |
| cR3 | P-3 | — | Q-3 | X-3 | — | A-3 | PGMEA/DAA/EL |
| | (80) | | (14) | (13) | | (1) | |
| cR4 | P-3 | — | Q-3 | X-3 | — | A-4 | PGMEA/DAA/EL |
| | (80) | | (14) | (13) | | (1) | |
| cR5 | P-3 | — | Q-3 | X-3 | — | — | PGMEA/DAA/EL |
| | (80) | | (14) | (13) | | | |
| cR6 | P-3 | — | Q-4 | — | — | — | PGMEA/DAA/EL |
| | (80) | | (14) | | | | |
| cR7 | cP-1 | PAG-1 | Q-1 | X-1 | T-1 | — | PGMEA/DAA/EL |
| | (80) | (5) | (14) | (13) | (5) | | |
| cR8 | cP-2 | — | Q-2 | X-2 | T-2 | — | PGMEA/DAA/EL |
| | (80) | | (14) | (13) | (5) | | |
| cR9 | P-3 | — | Q-3 | X-3 | cT-1 | — | PGMEA/DAA/EL |
| | (80) | | (14) | (13) | (5) | | |
| cR10 | P-3 | — | Q-3 | X-3 | cT-2 | — | PGMEA/DAA/EL |
| | (80) | | (14) | (13) | (5) | | |
| cR11 | P-3 | — | Q-3 | X-3 | cT-3 | — | PGMEA/DAA/EL |
| | (80) | | (14) | (13) | (5) | | |
| cR12 | P-3 | — | Q-3 | X-3 | cT-4 | — | PGMEA/DAA/EL |
| | (80) | | (14) | (13) | (5) | | |
| cR13 | P-3 | — | Q-3 | X-3 | cT-5 | — | PGMEA/DAA/EL |
| | (80) | | (14) | (13) | (5) | | |

### (2) Evaluation of Crosslinking Reactivity (Examples 1-1 to 1-19 and Comparative Examples 1-1 to 1-13)

The resist materials R¹ to R¹⁷ and cR1 to 13 were each applied on a Si substrate by spin-coating, and prebaked by using a hotplate for 60 seconds to produce a resist film with 50 nm in film thickness. This resist film was peeled from the substrate, dissolved in an organic solvent, and then the weight-average molecular weight in terms of polystyrene was measured by gel permeation chromatography (GPC) using dimethylformamide as a solvent. Table 3 shows the temperature during the prebaking and the molecular weight after the prebaking in the production of the resist films of Examples 1-1 to 1-19. Table 4 shows the above contents of Comparative Examples 1-1 to 1-13.

### (3) Evaluation of Dissolution Contrast (Examples 2-1 to 2-19 and Comparative Examples 2-1 to 2-9)

The resist materials R1 to R17 and cR5 to cR13 were each applied by spin-coating on DUV-42, an anti-reflective film manufactured by Nissan Chemical Corporation, produced with 61 nm in film thickness on a 8-inch wafer, and prebaked by using a hot plate for 60 seconds to produce a resist film with 50 nm in film thickness. This resist film was exposed by using a KrF exposure device (S206D, manufactured by NIKON CORPORATION), PEB was performed on a hot plate at 95° C. for 60 seconds, and development was performed with a 2.38 mass % TMAH aqueous solution for 30 seconds. The film thickness of this resist film after the development treatment was measured, and the relationship between the exposure dose and the resist film thickness after the development treatment was plotted to analyze the dissolution contrast. In addition, the contrast was evaluated in accordance with the following evaluation criteria as Examples 2-1 to 2-19 and Comparative Examples 2-1 to 2-9. Used for measuring the film thickness was VM-2210, a film thickness meter manufactured by Hitachi High-Technologies Corporation. Table 5 shows the results of Examples 2-1 to 2-19, and Table 6 shows the results of Comparative Examples 2-1 to 2-9.

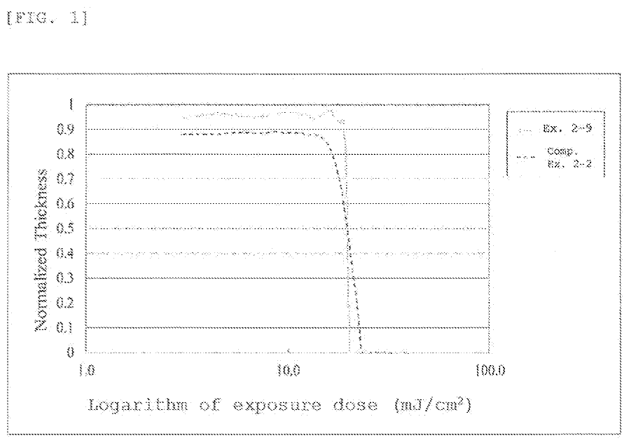

As a representative composition in the evaluation of the dissolution contrast, FIG. 1 indicates contrast curves of the resist films of Example 2-9 and Comparative Example 2-2. In FIG. 1, the vertical axis indicates the value of the film thickness after the development treatment normalized with the film thickness before the treatment. The value of contrast in Table 5 indicates the inclination of change in the film thickness relative to the exposure dose at the point where the solubility of the resist film in the developing liquid sharply changes. In the section from the point where the film thickness was 80% or less of the initial film thickness to the point where the film was completely dissolved, the inclination was regarded as the contrast value where the horizontal axis is set to logarithm of the exposure dose and the vertical axis is set to the normalized film thickness. The contrast of the resist film formed from each resist composition was evaluated based on the absolute value of the contrast value as follows.

### (Evaluation Criteria)

Excellent: The absolute value of the contrast value was 10 or more.
Good: The absolute value of the contrast value was 5 or more and less than 10.
Poor: The absolute value of the contrast value was less than 5.

### (4) Evaluation of Storage Stability (Examples 3-1 to 3-17 and Comparative Examples 3-1 to 3-4)

The resist materials shown in Table 1 and Table 2 were each stored at 40° C. or 23° C. for two weeks, and then applied by spin-coating on DUV-42, an anti-reflective film manufactured by Nissan Chemical Corporation, produced with 61 nm in film thickness on a 8-inch wafer, and prebaked by using a hot plate for 60 seconds to produce a resist film with approximately 50 nm in film thickness. Used for measuring the film thickness was VM-2210, a film thickness meter manufactured by Hitachi High-Technologies Corporation. This resist film was exposed by using a KrF exposure device (S206D, manufactured by NIKON CORPORATION, NA 0.68, σ0.75, 2/3 zonal illumination, 6% halftone phase-shifting), PEB was performed on a hot plate at 95° C. for 60 seconds, and development was performed with a 2.38 mass % TMAH aqueous solution for 30 seconds. The pattern after the development was observed with a length-measurement SEM (59380), manufactured by Hitachi High-Technologies Corporation, to evaluate sensitivity. Evaluated with the following evaluation criteria was the difference between the sensitivity of the 40° C.-stored resist material and the sensitivity of the 23° C.-stored resist material evaluated under the same condition. Table 7 shows the results of Examples 3-1 to 3-17, and Table 8 shows the results of Comparative Examples 3-1 to 3-4.

### (Evaluation Criteria)

Good: The sensitivity difference was less than 2%.
Poor: The sensitivity difference was 2% or more.

### (5) Lithography Evaluation (Examples 4-1 to 4-17 and Comparative Examples 4-1 to 4-9)

The resist materials R1 to R17 and cR5 to cR13, shown in Table 1 and Table 2, were each applied by spin-coating on DUV-42, an anti-reflective film manufactured by Nissan Chemical Corporation, produced with 61 nm in film thickness on a 8-inch wafer, and prebaked by using a hot plate for 60 seconds to produce a resist film with approximately 50 nm in film thickness. This resist film was exposed by using an electron beam writing device (ELS-F125, acceleration voltage 125 kV), manufactured by ELIONIX INC., PEB was performed on a hot plate at 95° C. for 60 seconds, and development was performed with a 2.38 mass % TMAH aqueous solution for 30 seconds. The pattern after the development was observed with a length-measurement SEM (S9380), manufactured by Hitachi High-Technologies Corporation. The tripled value (3σ) of a standard variation (σ) calculated from the results was determined as a pattern width variation (LWR). In addition, the pattern width variation was evaluated based on the following evaluation criteria. Table 9 shows the results of Examples 4-1 to 4-17, and Table 10 shows the results of Comparative Examples 4-1 to 4-9.

### (Evaluation Criteria)

Excellent: The LWR value was less than 3.0.
Good: The LWR value was 3.0 or more and less than 3.5.
Poor: The LWR value was 3.5 or more.

TABLE 3

| | | Prebaking | |
|---|---|---|---|
| | Resist | temperature | Molecular weight |
| Example | composition | (° C.) | after prebaking |
| Example 1-1 | R1 | 130 | 4.5 × 10⁴ |
| Example 1-2 | R2 | 130 | 1.0 × 10⁵ |
| Example 1-3 | R3 | 130 | 1.1 × 10⁵ |
| Example 1-4 | R4 | 130 | 1.8 × 10⁵ |
| Example 1-5 | R5 | 130 | 4.7 × 10⁴ |
| Example 1-6 | R6 | 130 | 3.9 × 10⁴ |
| Example 1-7 | R7 | 130 | 4.0 × 10⁴ |
| Example 1-8 | R8 | 130 | 1.1 × 10⁵ |
| Example 1-9 | R9 | 100 | 6.0 × 10⁴ |
| Example 1-10 | R9 | 130 | 1.4 × 10⁵ |
| Example 1-11 | R9 | 150 | Insoluble |
| Example 1-12 | R10 | 130 | 9.6 × 10⁴ |
| Example 1-13 | R11 | 130 | 4.5 × 10⁴ |
| Example 1-14 | R12 | 130 | 1.0 × 10⁵ |
| Example 1-15 | R13 | 130 | 1.2 × 10⁵ |
| Example 1-16 | R14 | 130 | 1.5 × 10⁵ |
| Example 1-17 | R15 | 130 | 5.8 × 10⁴ |
| Example 1-18 | R16 | 130 | 1.1 × 10⁵ |
| Example 1-19 | R17 | 130 | 9.7 × 10⁴ |

TABLE 4

| | | Prebaking | |
|---|---|---|---|
| | Resist | temperature | Molecular weight |
| Example | composition | (° C.) | after prebaking |
| Comparative | cR1 | 130 | 1.0 × 10⁴ |
| Example 1-1 | | | |
| Comparative | cR2 | 130 | 4.8 × 10⁴ |
| Example 1-2 | | | |
| Comparative | cR3 | 130 | 5.0 × 10⁴ |
| Example 1-3 | | | |
| Comparative | cR4 | 130 | 5.0 × 10⁴ |
| Example 1-4 | | | |
| Comparative | cR5 | 130 | 2.1 × 10⁴ |
| Example 1-5 | | | |
| Comparative | cR6 | 130 | 8.3 × 10³ |
| Example 1-6 | | | |
| Comparative | cR7 | 130 | 4.4 × 10³ |
| Example 1-7 | | | |
| Comparative | cR8 | 130 | 5.0 × 10³ |
| Example 1-8 | | | |
| Comparative | cR9 | 130 | 1.1 × 10⁴ |
| Example 1-9 | | | |
| Comparative | cR10 | 130 | 4.5 × 10⁴ |
| Example 1-10 | | | |
| Comparative | cR11 | 130 | 1.0 × 10⁴ |
| Example 1-11 | | | |
| Comparative | cR12 | 130 | 1.0 × 10⁴ |
| Example 1-12 | | | |
| Comparative | cR13 | 130 | 1.1 × 10⁴ |
| Example 1-13 | | | |

TABLE 5

| | | Prebaking | | |
|---|---|---|---|---|
| | Resist | temperature | | |
| Example | composition | (° C.) | Contrast | Evaluation |
| Example 2-1 | R1 | 130 | −5.1 | Good |
| Example 2-2 | R2 | 130 | −5.8 | Good |
| Example 2-3 | R3 | 130 | −6.4 | Good |
| Example 2-4 | R4 | 130 | −7.7 | Good |
| Example 2-5 | R5 | 130 | −5.8 | Good |
| Example 2-6 | R6 | 130 | −5.0 | Good |
| Example 2-7 | R7 | 130 | −5.1 | Good |
| Example 2-8 | R8 | 130 | −6.5 | Good |
| Example 2-9 | R9 | 100 | −5.0 | Good |
| Example 2-10 | R9 | 130 | −10.2 | Excellent |
| Example 2-11 | R9 | 150 | −11.1 | Excellent |
| Example 2-12 | R10 | 130 | −10.9 | Excellent |
| Example 2-13 | R11 | 130 | −6.4 | Good |
| Example 2-14 | R12 | 130 | −10.6 | Excellent |
| Example 2-15 | R13 | 130 | −10.4 | Excellent |
| Example 2-16 | R14 | 130 | −11.5 | Excellent |
| Example 2-17 | R15 | 130 | −5.4 | Good |
| Example 2-18 | R16 | 130 | −10.2 | Excellent |
| Example 2-19 | R17 | 130 | −6.2 | Good |

TABLE 6

| | | Prebaking | | |
|---|---|---|---|---|
| | Resist | temperature | | |
| Example | composition | (° C.) | Contrast | Evaluation |
| Comparative | cR5 | 130 | −3.7 | Poor |
| Example 2-1 | | | | |
| Comparative | cR6 | 130 | −2.8 | Poor |
| Example 2-2 | | | | |
| Comparative | cR7 | 130 | −2.0 | Poor |
| Example 2-3 | | | | |
| Comparative | cR8 | 130 | −2.1 | Poor |
| Example 2-4 | | | | |
| Comparative | cR9 | 130 | −4.2 | Poor |
| Example 2-5 | | | | |
| Comparative | cR10 | 130 | −4.4 | Poor |
| Example 2-6 | | | | |
| Comparative | cR11 | 130 | −4.4 | Poor |
| Example 2-7 | | | | |
| Comparative | cR12 | 130 | −3.7 | Poor |
| Example 2-8 | | | | |
| Comparative | cR13 | 130 | −3.8 | Poor |
| Example 2-9 | | | | |

TABLE 7

| | Resist | Film thickness | Sensitivity | |
|---|---|---|---|---|
| Example | composition | (Å) | difference | Evaluation |
| Example 3-1 | R1 | 0.8 | 1.21% | Good |
| Example 3-2 | R2 | 1.2 | 1.50% | Good |
| Example 3-3 | R3 | 1.2 | 1.44% | Good |
| Example 3-4 | R4 | 1.5 | 1.73% | Good |
| Example 3-5 | R5 | 1.0 | 1.43% | Good |
| Example 3-6 | R6 | 1.4 | 1.55% | Good |
| Example 3-7 | R7 | 0.8 | 1.14% | Good |
| Example 3-8 | R8 | 1.3 | 1.29% | Good |
| Example 3-9 | R9 | 0.7 | 1.10% | Good |
| Example 3-10 | R10 | 1.0 | 1.23% | Good |
| Example 3-11 | R11 | 0.6 | 0.92% | Good |
| Example 3-12 | R12 | 0.7 | 0.95% | Good |
| Example 3-13 | R13 | 0.7 | 0.80% | Good |
| Example 3-14 | R14 | 1.4 | 1.60% | Good |
| Example 3-15 | R15 | 1.8 | 1.59% | Good |
| Example 3-16 | R16 | 1.0 | 1.05% | Good |
| Example 3-17 | R17 | 1.9 | 1.84% | Good |

TABLE 8

| | Resist | Film thickness | Sensitivity | |
|---|---|---|---|---|
| Example | composition | (Å) | difference | Evaluation |
| Comparative | cR1 | 10.4 | 4.51% | Poor |
| Example 3-1 | | | | |
| Comparative | cR2 | 11.1 | 5.37% | Poor |
| Example 3-2 | | | | |
| Comparative | cR3 | 8.8 | 3.96% | Poor |
| Example 3-3 | | | | |
| Comparative | cR4 | 7.3 | 3.83% | Poor |
| Example 3-4 | | | | |

TABLE 9

| | Resist | | |
|---|---|---|---|
| Example | composition | LWR | Evaluation |
| Example 4-1 | R1 | 3.44 | Good |
| Example 4-2 | R2 | 3.01 | Good |
| Example 4-3 | R3 | 3.13 | Good |
| Example 4-4 | R4 | 3.36 | Good |
| Example 4-5 | R5 | 3.47 | Good |
| Example 4-6 | R6 | 3.40 | Good |
| Example 4-7 | R7 | 3.44 | Good |
| Example 4-8 | R8 | 3.48 | Good |
| Example 4-9 | R9 | 2.40 | Excellent |
| Example 4-10 | R10 | 2.35 | Excellent |
| Example 4-11 | R11 | 2.39 | Excellent |
| Example 4-12 | R12 | 2.53 | Excellent |
| Example 4-13 | R13 | 2.53 | Excellent |
| Example 4-14 | R14 | 2.59 | Excellent |
| Example 4-15 | R15 | 2.80 | Excellent |
| Example 4-16 | R16 | 2.64 | Excellent |
| Example 4-17 | R17 | 3.52 | Good |

TABLE 10

| | Resist | | |
|---|---|---|---|
| Example | composition | LWR | Evaluation |
| Comparative | cR5 | 3.22 | Good |
| Example 4-1 | | | |
| Comparative | cR6 | 3.15 | Good |
| Example 4-2 | | | |
| Comparative | cR7 | 4.25 | Poor |
| Example 4-3 | | | |
| Comparative | cR8 | 4.16 | Poor |
| Example 4-4 | | | |
| Comparative | cR9 | 3.72 | Poor |
| Example 4-5 | | | |
| Comparative | cR10 | 3.81 | Poor |
| Example 4-6 | | | |
| Comparative | cR11 | 3.81 | Poor |
| Example 4-7 | | | |
| Comparative | cR12 | 3.74 | Poor |
| Example 4-8 | | | |
| Comparative | cR13 | 3.66 | Poor |
| Example 4-9 | | | |

As shown in Table 3 and Table 4, Examples 1-1 to 1-19, which contained the vinyl ether crosslinker and the thermal acid generator, increased the average molecular weight after the prebaking. It was suggested that the crosslinking reaction proceeded. It was found in Example 1-11 that the resist film after prebaking was such a crosslinked product that it was insoluble in the GPC solvent. Meanwhile, when the sulfonic acid-type or sulfonate salt-type thermal acid generator, or the carboxylate salt-type thermal acid generator having no fluorine atom was added, the effect of increasing the molecular weight was not observed. It is suggested that: the acid generated from the thermal acid generator fails to function as a crosslinking catalyst when its acidity is excessively weak; and the acid proceeds decomposition reaction of the acetal bond immediately after the crosslinking when its acidity is excessively strong. It was found that regulating the acidity of the generated acid was important.

As shown in FIG. 1, Example 2-9 significantly differs from Comparative Example 2-2 in the solubility difference between the exposed portion and the unexposed portion, and it can be confirmed that the film thickness after the development treatment sharply changes relative to the exposure dose. The contrast values in Table 5 and Table 6, which indicate the inclination of this change in the film thickness, become positive inclination for a negative-type resist and become negative inclination for a positive-type resist. A larger absolute value thereof indicates more excellent dissolution contrast. Examples 2-1 to 2-19, which contained the polymer having the reactive group, the crosslinker, and the fluorocarboxylate salt-type thermal acid generator, all exhibited good contrast. It is considered that the good contrast is derived from the promoted crosslinking in the unexposed portion by the thermal acid generator. It have been unveiled that the resist containing the vinyl ether having a larger amount of crosslinking positions exhibits better contrast. In addition, the resist composition having the structural unit (C) to generate an acid by light in the base polymer exhibited particularly excellent contrast. Since the structural unit (C) has high polarity and hydrophilicity, a not-crosslinked low molecular-weight product having the (C) has high solubility in the developing liquid. Meanwhile, increasing the molecular weight of such an easily soluble component with crosslinking significantly decreases the solubility in the developing liquid. This effect can largely change the dissolution contrast between the exposed and unexposed portions. Therefore, the base polymer preferably has the structural unit (C).

The resist films using the resist compositions cR1 to cR4, which contained no thermal acid generator and contained a small amount of the acids A-1 to A-4 as the crosslinking enhancer, became thick during the long-term storage, and the sensitivity difference also became large to lower the sensitivity, as shown in Comparative Examples 3-1 to 3-4 in Table 8. This is presumably a change resulting from the fact that Comparative Examples 3-1 to 3-4, which contain the acid as the crosslinking enhancer, proceed the crosslinking reaction during the storage as the solution to increase the molecular weight of the polymer. Therefore, it has been shown that, although having the structural unit (C), the resist material having no thermal acid generator exhibits poor storage stability.

As shown in Table 9, Examples 4-1 to 4-17, which contained the polymer having the reactive group, the crosslinker, and the fluorocarboxylate salt-type thermal acid generator, all exhibited good LWR. In addition, the resist composition having the structural unit (C) to generate an acid by light in the base polymer exhibited particularly excellent LWR.

From the above results, the inventive resist material satisfies the high dissolution contrast and the good LWR. Therefore, the inventive resist material has been demonstrated to be a resist material having reduced edge roughness and size variation, excellent resolution, good pattern shape after the exposure, and good storage stability.

It should be noted that the present invention is not limited to the above-described embodiments. The embodiments are just examples, and any examples that substantially have the same feature and demonstrate the same functions and effects as those in the technical concept disclosed in claims of the present invention are included in the technical scope of the present invention.

1. A resist material, comprising:
(Ia) a polymer having a repeating unit (A) having a hydroxy group or a carboxy group;
(II) a crosslinker having a structure represented by the following formula (1);
(III) a thermal acid generator having a structure represented by the following formula (2);
(IV) an organic solvent; and
(V) a component to be decomposed by irradiation of active ray or radiation to generate an acid, 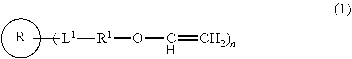
wherein R represents an n-valent organic group optionally having a substituent,
L¹ represents a linking group selected from a single bond, an ester bond, and an ether bond, and
R¹ represents a single bond or a divalent organic group, and “n” represents an integer of 1 to 4, 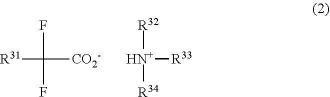
wherein R³¹ represents a monovalent organic group optionally having a heteroatom or a substituent; R³² to R³⁴ each independently represent a monovalent hydrocarbon group having 1 to 15 carbon atoms and optionally having a heteroatom, and any two of R³², R³³, and R³⁴ are optionally bonded each other to from a ring together with the nitrogen atom to which R³², R³³, and R³⁴ are bonded.

2. A resist material, comprising:
(Ib) a polymer having: a repeating unit (A) having a hydroxy group or a carboxy group; and a repeating unit (C) having a structural moiety to be decomposed by irradiation of active ray or radiation to generate an acid;
(II) a crosslinker having a structure represented by the following formula (1);
(III) a thermal acid generator having a structure represented by the following formula (2); and
(IV) an organic solvent, 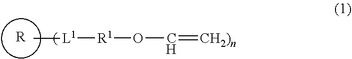
wherein R represents an n-valent organic group optionally having a substituent;
L¹ represents a linking group selected from a single bond, an ester bond, and an ether bond; and
R¹ represents a single bond or a divalent organic group, and “n” represents an integer of 1 to 4, 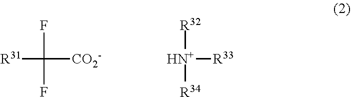
wherein R³¹ represents a monovalent organic group optionally having a heteroatom or a substituent; and R³² to R³⁴ each independently represent a monovalent hydrocarbon group having 1 to 15 carbon atoms and optionally having a heteroatom, and any two of R³², R³³, and R³⁴ are optionally bonded each other to from a ring together with the nitrogen atom to which R³², R³³, and R³⁴ are bonded.

3. The resist material according to claim 2, wherein the repeating unit (C) in the polymer is represented by the following formula (c), 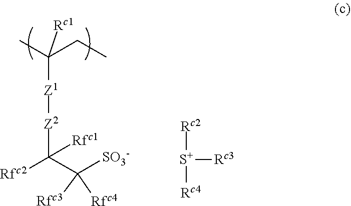
wherein R^{c1} represents a hydrogen atom or a methyl group;
Z¹ represents a single bond or an ester bond; Z² represents a single bond or a divalent organic group having 1 to 25 carbon atoms and optionally having one or more of an ester bond, an ether bond, a lactone ring, an amide bond, a sultone ring, and an iodine atom;
Rf^{c1} to Rf^{c4} each independently represent a hydrogen atom, a fluorine atom, or a trifluoromethyl group, and at least one of Rf^{c1} to Rf^{c4} represents a fluorine atom or a trifluoromethyl group; and
R^{c2} to R^{c4} each independently represent a monovalent hydrocarbon group having 1 to 20 carbon atoms and optionally having a heteroatom, and any two of R^{c2}, R^{c3}, and R^{c4} are optionally bonded each other to form a ring together with the sulfur atom to which R^{c2}, R^{c3}, and R^{c4} are bonded.

4. The resist material according to claim 2, further comprising (V) a component to be decomposed by irradiation of active ray or radiation to generate an acid.

5. The resist material according to claim 3, further comprising (V) a component to be decomposed by irradiation of active ray or radiation to generate an acid.

6. The resist material according to claim 1, wherein the repeating unit (A) in the polymer is represented by the following formulae (a1) and/or (a2), 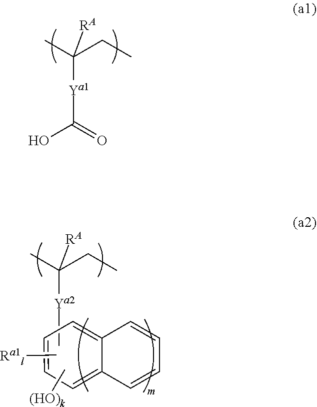
wherein R^{A} each independently represents a hydrogen atom or a methyl group; Y^{a1} each independently represents a single bond or a divalent linking group having 1 to 15 carbon atoms and having at least one or more of a phenylene group, a naphthylene group, an ester bond, an ether bond, a lactone ring, an amide group, and a heteroatom; Y^{a2} each independently represents a single bond or a divalent linking group having 1 to 12 carbon atoms and having at least one or more of a phenylene group, a naphthylene group, an ester bond, an ether bond, a lactone ring, an amide group, and a heteroatom; R^{a1} represents a hydrogen atom, a fluorine atom, or an alkyl group, and R^{a1} and Y^{a2} are optionally bonded to form a ring; “k” represents 1 or 2; “l” represents an integer of 0 to 4; 1≤k+l≤5; and “m” represents 0 or 1.

7. The resist material according to claim 2, wherein the repeating unit (A) in the polymer is represented by the following formulae (a1) and/or (a2), 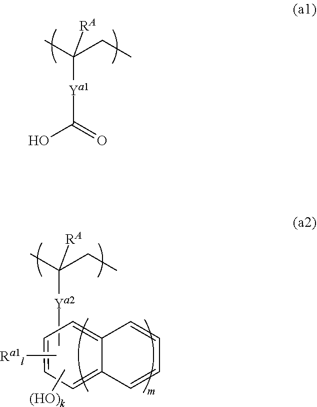
wherein R^{A} each independently represents a hydrogen atom or a methyl group; Y^{a1} each independently represents a single bond or a divalent linking group having 1 to 15 carbon atoms and having at least one or more of a phenylene group, a naphthylene group, an ester bond, an ether bond, a lactone ring, an amide group, and a heteroatom; Y^{a2} each independently represents a single bond or a divalent linking group having 1 to 12 carbon atoms and having at least one or more of a phenylene group, a naphthylene group, an ester bond, an ether bond, a lactone ring, an amide group, and a heteroatom; R^{a1} represents a hydrogen atom, a fluorine atom, or an alkyl group, and R^{a1} and Y^{a2} are optionally bonded to form a ring; “k” represents 1 or 2; “l” represents an integer of 0 to 4; 1≤k+l≤5; and “m” represents 0 or 1.

8. The resist material according to claim 3, wherein the repeating unit (A) in the polymer is represented by the following formulae (a1) and/or (a2), 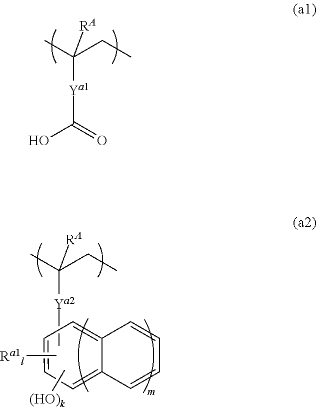
wherein R^{A} each independently represents a hydrogen atom or a methyl group; Y^{a1} each independently represents a single bond or a divalent linking group having 1 to 15 carbon atoms and having at least one or more of a phenylene group, a naphthylene group, an ester bond, an ether bond, a lactone ring, an amide group, and a heteroatom; Y^{a2} each independently represents a single bond or a divalent linking group having 1 to 12 carbon atoms and having at least one or more of a phenylene group, a naphthylene group, an ester bond, an ether bond, a lactone ring, an amide group, and a heteroatom; R^{a1} represents a hydrogen atom, a fluorine atom, or an alkyl group, and R^{a1} and Y^{a2} are optionally bonded to form a ring; “k” represents 1 or 2; “l” represents an integer of 0 to 4; 1≤k+l≤5; and “m” represents 0 or 1.

9. The resist material according to claim 4, wherein the repeating unit (A) in the polymer is represented by the following formulae (a1) and/or (a2), 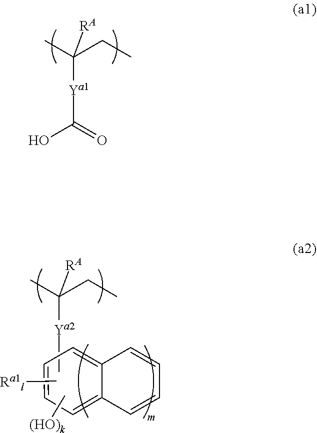
wherein R^{A} each independently represents a hydrogen atom or a methyl group; Y^{a1} each independently represents a single bond or a divalent linking group having 1 to 15 carbon atoms and having at least one or more of a phenylene group, a naphthylene group, an ester bond, an ether bond, a lactone ring, an amide group, and a heteroatom; Y^{a2} each independently represents a single bond or a divalent linking group having 1 to 12 carbon atoms and having at least one or more of a phenylene group, a naphthylene group, an ester bond, an ether bond, a lactone ring, an amide group, and a heteroatom; R^{a1} represents a hydrogen atom, a fluorine atom, or an alkyl group, and R^{a1} and Y^{a2} are optionally bonded to form a ring; “k” represents 1 or 2; “l” represents an integer of 0 to 4; 1≤k+l≤5; and “m” represents 0 or 1.

10. The resist material according to claim 5, wherein the repeating unit (A) in the polymer is represented by the following formulae (a1) and/or (a2), 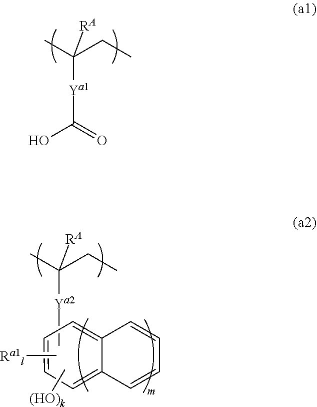
wherein R^{A} each independently represents a hydrogen atom or a methyl group; Y^{a1} each independently represents a single bond or a divalent linking group having 1 to 15 carbon atoms and having at least one or more of a phenylene group, a naphthylene group, an ester bond, an ether bond, a lactone ring, an amide group, and a heteroatom; Y^{a2} each independently represents a single bond or a divalent linking group having 1 to 12 carbon atoms and having at least one or more of a phenylene group, a naphthylene group, an ester bond, an ether bond, a lactone ring, an amide group, and a heteroatom; R^{a1} represents a hydrogen atom, a fluorine atom, or an alkyl group, and R^{a1} and Y^{a2} are optionally bonded to form a ring; “k” represents 1 or 2; “l” represents an integer of 0 to 4; 1≤k+l≤5; and “m” represents 0 or 1.

11. The resist material according to claim 1, wherein R³¹ in the formula (2) has an iodine atom.

12. The resist material according to claim 2, wherein R³¹ in the formula (2) has an iodine atom.

13. The resist material according to claim 3, wherein R³¹ in the formula (2) has an iodine atom.

14. The resist material according to claim 4, wherein R³¹ in the formula (2) has an iodine atom.

15. The resist material according to claim 5, wherein R³¹ in the formula (2) has an iodine atom.

16. The resist material according to claim 1, wherein R in the formula (1) has an aromatic hydrocarbon group.

17. The resist material according to claim 2, wherein R in the formula (1) has an aromatic hydrocarbon group.

18. The resist material according to claim 1, further comprising (VI) a quencher.

19. A patterning process, comprising:
(i) a step of forming a resist film by applying a resist material on a substrate using the resist material according to claim 1;
(ii) a step of exposing the resist film with a high-energy ray; and
(iii) a step of developing the exposed resist film using a developing liquid.

20. The patterning process according to claim 19, wherein the step (i) further comprising a step of prebaking the resist film at 130° C. or higher.
